(19) United States
(12) Patent Application Publication
(10) Pub. No.: US 2025/0254941 A1
(43) Pub. Date: Aug. 7, 2025

(54) OPTICALLY ADDRESSABLE ACTUATORS AND RELATED METHODS

(71) Applicant: President and Fellows of Harvard College, Cambridge, MA (US)

(72) Inventors: Ehsan Hajiesmaili, Cambridge, MA (US); David Clarke, Cambridge, MA (US)

(73) Assignee: President and Fellows of Harvard College, Cambridge, MA (US)

(21) Appl. No.: 18/856,591

(22) PCT Filed: Apr. 11, 2023
(86) PCT No.: PCT/US2023/018193

§ 371 Date: Oct. 11, 2024

Related U.S. Application Data
(60) Provisional application No. 63/330,206, filed on Apr. 12, 2022.

(51) Int. Cl. H10D 62/10; B82Y 15/00; B82Y 30/00; H10D 62/00; H10D 62/86; H10F 55/00

(52) U.S. Cl. CPC H10D 62/121; B82Y 15/00; B82Y 30/00; H10D 62/01; H10D 62/86; H10F 55/18

(57) ABSTRACT

Addressable actuator and arrays thereof are described. Actuators may be dielectric elastomer actuators (DBAs). An addressable actuator may include a compliant substrate, with an optical receiver integrated with a first region of the compliant substrate and an actuator integrated with a second region of the compliant substrate, with the optical receiver coupled to the actuator. The optical receivers may comprise percolating networks of semiconductor materials, such as photoconductive channels of zinc oxide nanowires, which may be embedded in a compliant substate, or one or more compliant layers (which may be formed on a substrate). Compliant substrates or layers may include complaint materials such as an elastomer. An actuator array may comprise multiple of the actuators, with each actuator being independently optically addressable. A system may include light emitting devices optically coupled to respective optical receivers to control actuation of the actuators using light.

### RELATED APPLICATIONS

This Application claims the benefit under 35 USC 119 (e) of U.S. Provisional Application Ser. No. 63/330,206, filed Apr. 12, 2022, under attorney docket number H0776.70147US00 and entitled “OPTICAL ADDRESSING OF DIELECTRIC ELASTOMER ACTUATORS”, which is hereby incorporated herein by reference in its entirety.

### GOVERNMENT SPONSORSHIP

This invention was made with government support under 2011754 awarded by National Science Foundation (NSF). The government has certain rights in this invention.

### FIELD

The technology of the disclosure relates to compliant actuators and arrays thereof.

### BACKGROUND

Compliant actuators, such as dielectric elastomer actuators (DEAs), and arrays thereof may be employed in soft robot, haptic device, or other environments.

### SUMMARY

According to aspects of the disclosure, there is provided an addressable actuator, comprising a compliant substrate including a first region and a second region, an optical receiver integrated with the first region of the compliant substrate, and an actuator integrated with the second region of the compliant substrate, wherein the optical receiver is coupled to the actuator.

In some embodiments, an addressable actuator array comprises a plurality addressable actuators, wherein each addressable actuator of the plurality of addressable actuators comprises the addressable actuator.

In some embodiments, each addressable actuator of the plurality of addressable actuators is independently optically addressable.

In some embodiments, a system comprises the addressable actuator and a light emitting device, wherein the light emitting device is optically coupled to the optical receiver.

In some embodiments, the optical receiver comprises a photoconductive channel integrated with the actuator.

In some embodiments, the photoconductive channel is compliant.

In some embodiments, the compliant substrate comprises an elastomer.

In some embodiments, the optical receiver is electrically coupled to the actuator.

In some embodiments, the optical receiver is directly electrically coupled to the actuator.

In some embodiments, the optical receiver comprises a semiconductor film.

In some embodiments, the optical receiver comprises a plurality of zinc oxide nanowires disposed in the first region of the compliant substrate.

In some embodiments, the plurality of zine oxide nanowires comprise a percolating network.

In some embodiments, the actuator comprises a capacitor, the capacitor comprising a first electrode, a second electrode, and a portion of the compliant substrate disposed between the first electrode and the second electrode.

In some embodiments, the capacitor is configured to receive a signal from the optical receiver and responsive to receiving the signal, compress a thickness of the portion of the compliant substrate disposed between the first electrode and the second electrode.

In some embodiments, the capacitor is further configured to responsive to receiving the signal, laterally expand the portion of the compliant substrate disposed between the first electrode.

In some embodiments, the optical receiver is formed of a first material and at least one of the first electrode or the second electrode is formed of the first material.

In some embodiments, the first material comprises zinc oxide.

In some embodiments, the optical receiver, the first electrode, and the second electrode are formed of zinc oxide nanowires.

In some embodiments, the first region and the second region overlap.

According to aspects of the disclosure, there is provided a method of manufacturing an addressable actuator, comprising forming a compliant substrate including a first region and a second region, integrating an optical receiver with the first region of the compliant substrate, and integrating an actuator with the second region of the compliant substrate, wherein the optical receiver is coupled to the actuator.

In some embodiments, a method of manufacturing an addressable actuator array, comprises forming a plurality of addressable actuators, comprising forming each addressable actuator of the plurality of addressable actuators according to the method of manufacturing the addressable actuator.

In some embodiments, each addressable actuator of the plurality of addressable actuators is independently optically addressable.

In some embodiments, a method of manufacturing a system, comprises forming an addressable actuator according to the method of manufacturing the addressable actuator, providing a light emitting device, and optically coupling the light emitting device to the optical receiver.

In some embodiments, integrating an optical receiver comprises integrating a photoconductive channel with the actuator.

In some embodiments, the photoconductive channel is compliant.

In some embodiments, forming the compliant substrate comprises forming the compliant substrate with an elastomer.

In some embodiments, the method further comprises electrically coupling the optical receiver to the actuator.

In some embodiments, electrically coupling the optical receiver to the actuator comprises directly electrically coupling the optical receiver to the actuator.

In some embodiments, integrating the optical receiver comprises forming the optical receiver with a semiconductor film.

In some embodiments, integrating the optical receiver comprises forming the optical receiver with a plurality of zinc oxide nanowires in the first region of the compliant substrate.

In some embodiments, forming the optical receiver with the plurality of zinc oxide nanowires comprises forming a percolating network with the plurality of zine oxide nanowires.

In some embodiments, integrating the actuator comprises forming a capacitor, comprising forming a first electrode and forming a second electrode, wherein a portion of the compliant substrate is disposed between the first electrode and the second electrode.

In some embodiments, the capacitor is configured to receive a signal from the optical receiver and responsive to receiving the signal, compress a thickness of the portion of the compliant substrate disposed between the first electrode and the second electrode.

In some embodiments, the capacitor is further configured to responsive to receiving the signal, laterally expand the portion of the compliant substrate disposed between the first electrode and the second electrode.

In some embodiments, the method comprises forming the optical receiver of a first material and forming at least one of the first electrode or the second electrode of the first material.

In some embodiments, the method comprises forming the optical receiver of zinc oxide and forming at least one of the first electrode or the second electrode of zinc oxide.

In some embodiments, the method comprises forming the optical receiver, the first electrode, and the second electrode of zinc oxide nanowires.

In some embodiments, integrating the optical receiver with the first region of the compliant substrate and integrating the actuator with the second region of the compliant substrate comprise integrating the optical receiver with the first region of the compliant substrate and integrating the actuator with the second region of the compliant substrate with the first region and the second region overlapping.

According to aspects of the disclosure, there is provided a method of operating an addressable actuator comprising a compliant substrate, the method comprising receiving an optical signal using an optical receiver integrated with a first region of the compliant substrate and responsive to receiving the optical signal, actuating an actuator integrated with a second region of the compliant substrate.

In some embodiments, a method of operating an addressable actuator array comprises operating a plurality of addressable actuators, comprising operating each addressable actuator of the plurality of addressable actuators according to the method of operating an addressable actuator.

In some embodiments, each addressable actuator of the plurality of addressable actuators is independently optically addressable.

In some embodiments, a method of operating a system comprises operating the addressable actuator according to the method of operating an addressable actuator and sending the optical signal using a light emitting device, wherein the light emitting device is optically coupled to the optical receiver.

In some embodiments, the optical receiver comprises a photoconductive channel integrated with the actuator.

In some embodiments, the photoconductive channel is compliant.

In some embodiments, the compliant substrate comprises an elastomer.

In some embodiments, the optical receiver is electrically coupled to the actuator.

In some embodiments, the optical receiver is directly electrically coupled to the actuator.

In some embodiments, the optical receiver comprises a semiconductor film.

In some embodiments, the optical receiver comprises a plurality of zinc oxide nanowires disposed in the first region of the compliant substrate.

In some embodiments, the plurality of zine oxide nanowires comprise a percolating network.

In some embodiments, the actuator comprises a capacitor, the capacitor comprising a first electrode, a second electrode, and a portion of the compliant substrate disposed between the first electrode and the second electrode.

In some embodiments, actuating the actuator comprises actuating the capacitor, comprising receiving a signal from the optical receiver and responsive to receiving the signal, compressing a thickness of the portion of the compliant substrate disposed between the first electrode and the second electrode.

In some embodiments, actuating the capacitor further comprises responsive to receiving the signal, laterally expanding the portion of the compliant substrate disposed between the first electrode and the second electrode.

In some embodiments, the optical receiver is formed of a first material and at least one of the first electrode or the second electrode is formed of the first material.

In some embodiments, the first material comprises zinc oxide.

In some embodiments, the optical receiver, the first electrode, and the second electrode are formed of zinc oxide nanowires.

In some embodiments, the first region and the second region overlap.

### BRIEF DESCRIPTION OF DRAWINGS

Various aspects and embodiments of the disclosure will be described with reference to the following figures. It should be appreciated that the figures are not necessarily drawn to scale. Items appearing in multiple figures may be indicated by the same reference number in figures in which they appear.

FIG. 1 shows an exemplary embodiment of an actuator system;

FIG. 2 shows an exemplary embodiment of an optical receiver;

FIGS. 3A-3B show additional exemplary embodiments of actuator systems;

FIGS. 4A-3F show additional exemplary embodiments of actuator systems;

FIGS. 5A-5G show additional exemplary embodiments of actuator systems;

FIGS. 6A-6B show exemplary embodiments of photoconductive channels;

FIG. 7 show an exemplary embodiment of breakdown of photoconductive material;

FIG. 8 shows an exemplary embodiment of a bandgap of a semiconductor material;

FIG. 9 shows an additional exemplary embodiment of an actuator system;

FIGS. 10A-10C show exemplary characterizations of actuator systems;

FIGS. 11A-11C show additional exemplary characterizations of actuator systems;

FIGS. 12A-12T show additional exemplary characterizations of actuator systems;

FIGS. 13A-13H show additional exemplary characterizations of actuator systems;

FIGS. 14A-14B show additional exemplary characterizations of actuator systems;

FIGS. 15A-15H show additional exemplary characterizations of actuator systems;

FIGS. 16A-16B show additional exemplary characterizations of actuator systems;

FIG. 17 shows exemplary characterizations of photoconductive materials;

FIG. 18 shows exemplary stress and stretch characterizations of components of actuator systems;

FIGS. 19A-19C show additional exemplary embodiments of actuator systems;

FIGS. 20A-20D show additional exemplary embodiments of actuator systems;

FIGS. 21A-21C show additional exemplary embodiments of actuator systems;

FIG. 22 shows an exemplary block diagram of a special purpose computer system that can be improved over conventional implementations based on implementations and/or execution of methods discussed herein;

FIG. 23 shows an exemplary process flow of a method of manufacturing an actuator; and

FIG. 24 shows an exemplary process flow of a method of operating an actuator.

### DETAILED DESCRIPTION

Addressable actuator and arrays thereof are described. Actuators may be dielectric elastomer actuators (DEAs). An addressable actuator may include a compliant substrate, with an optical receiver integrated with a first region of the compliant substrate and an actuator integrated with a second region of the compliant substrate, with the optical receiver coupled to the actuator. The optical receivers may comprise percolating networks of semiconductor materials, such as photoconductive channels of zinc oxide nanowires, which may be embedded in a compliant substate, or one or more compliant layers (which may be formed on a substrate). Compliant substrates or layers may include complaint materials such as an elastomer. An actuator array may comprise multiple of the actuators, with each actuator being independently optically addressable. A system may include light emitting devices optically coupled to respective optical receivers to control actuation of the actuators using light.

Aspects of the disclosure provide novel addressable actuators with an optical receiver integrated with a first region of a compliant substrate and an actuator integrated with a second region of the compliant substrate. As described herein, the addressable actuators, arrays thereof, and systems incorporating the arrays may be employed in soft robot, haptic device, or other environments. Addressable actuators according to the disclosure may provide for arrays having a greater number of independently addressable actuators, and therefore greater resolution of actuators, which may increase the versatility of the arrays for use in soft robot, haptic device, or other environments. In some embodiments, manufacturing addressable actuators according to methods described herein may simplify the fabrication of addressable actuators compared to conventional methods.

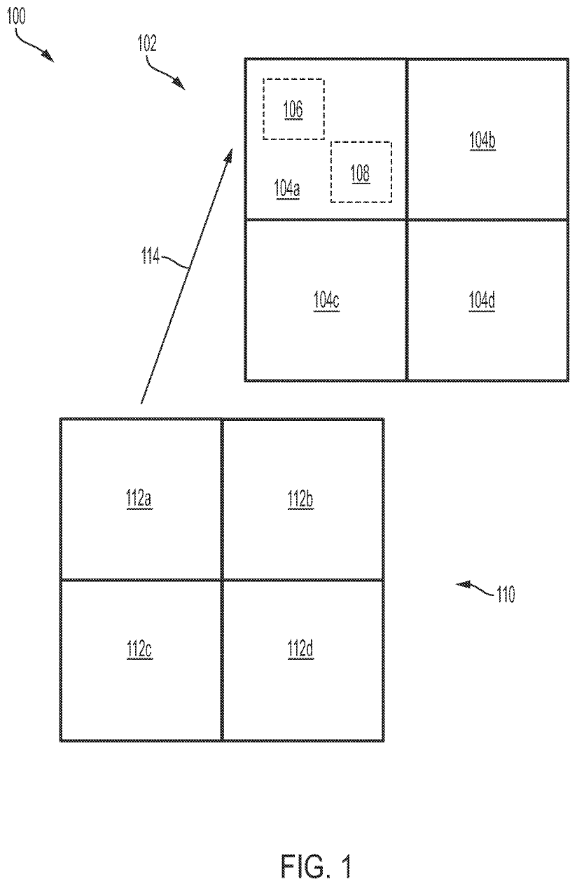

FIG. 1 shows an actuator system 100, comprising an actuator array including a compliant substrate 102 and a light emitting device array 110. For clarity of illustration, the compliant substrate 102 and the light emitting device array 110 are illustrated separately, but in practice the compliant substrate 102 and the light emitting device array 110 may be coupled with each other, for example, with one attached on top of the other, such as by bonding.

A compliant substrate such as compliant substrate 102 may be formed of a compliant material. A compliant material may comprise a material that is flexible and/or stretchable, such as a material that is both flexible and stretchable. In some embodiments, a flexible material may flex in bending. In some embodiments, a stretchable material may stretch in tension. For example, in various embodiments, a compliant substate such as compliant substrate 102 may comprise an elastomer or a dielectric material.

In some embodiments, a compliant substrate, such as compliant substrate 102, may comprise one or more compliant layers. For example, in some embodiments, a compliant substrate may include several layers interleaved with one or more electrodes. In some such embodiments, the compliant substrate may comprise at least three, at least five, or at least ten layers, with an electrode integrated between each of the layers. In embodiments where a compliant substrate includes two or more layers, a first compliant layer may be formed, then an electrode may be integrated with the first compliant layer, and then a compliant second layer may be integrated over the electrode. In further embodiments, after the second compliant layer is formed, additional electrodes and compliant layers may be integrated over the second compliant layer. In embodiments where a substrate includes more than one layer, some of the layers may be of a different compositions. For example, where an addressable actuator is formed layer-by-layer, a first layer may of a different material than the material of a layer disposed between electrodes.

The actuator array comprises a plurality of addressable actuators 104a, 104b, 104c, and 104d, each of which may comprise an actuator formed in compliant substate 102. Addressable actuator 104a is illustrated as including an optical receiver 106 integrated with a first region and an actuator 108 integrated with a second region. The optical receiver 106 and the actuator 108 may each be integrated with the compliant substrate 102. For example, optical receiver 106 and the actuator 108 may be formed directly on the compliant substrate. The other addressable actuators 104b, 104c, and 104d may each also include an optical receiver and actuator similar to optical receiver 106 and actuator 108, though they are not illustrated, for clarity of illustration. The optical receiver 106 and the actuator 108 may be operatively coupled to each other, for example, they may be electrically coupled such that they may pass an electrical signal therebetween.

A shown in FIG. 1, the system 100 may include an addressable actuator array, comprising the plurality addressable actuators, 104a, 104b, 104c, and 104d. Each addressable actuator of an array may be configured similar as addressable actuator 104a. Moreover, each addressable actuator may be independently optically addressable.

Referring still to FIG. 1, system 100 may further include a light emitting device array 110, which includes a plurality of light emitting devices 112a, 112b, 112c, and 112d. Each light emitting device may be optically coupled to a respective optical receiver, for example, with light emitting device 112a may be coupled to optical receiver 106 of addressable actuator 104a, light emitting device 112b may be coupled to an optical receiver of actuator 104b, light emitting device 112c may be coupled to an optical receiver of addressable actuator 104c, and light emitting device 112d may be coupled to an optical receiver of actuator addressable 104d.

Light emitting devices may be configured to control actuators using light signals. For example, as shown in FIG. 1, light emitting device 112a may be configured to control addressable actuator 104a by transmitting light signal 114 to optical receiver 106. When optical receiver receives the light signal 114, it may be configured to pass an electrical signa to actuator 108, which may cause actuator 108 to actuate.

An optical receiver such as optical receiver 106 may comprise photoconductive channel integrated with the actuator. As optical receivers may be integrated in the compliant substate 102, the photoconductive channel may similarly be configured to be compliant so that it may bend with the substrate. An optical receiver may be formed of a semiconductor material and may comprise a semiconductor film. For example, the optical receiver may comprise a plurality of zinc oxide nanowires disposed in the first region of the compliant substrate. As further described below, the plurality of zine oxide nanowires may be disposed in the substrate to form a percolating network.

According to some embodiments, an actuator such as actuator 106 may comprise a capacitor. Such a capacitor may include a first electrode and a second electrode, with a portion of a compliant substrate disposed between the first electrode and the second electrode. When the capacitor receives a signal from an optical receiver the capacitor may compress a thickness of the portion of the compliant substrate disposed between the first electrode, which may further laterally expand the portion of the compliant substrate disposed between the first electrode, based on an incompressibility of the substrate.

In some embodiments, the optical receiver and at least one of the electrodes of the capacitor may be formed of a same first material. The same material may be zinc oxide, such that the optical receiver, the first electrode, and the second electrode are each formed of zinc oxide nanowires.

In various embodiments, an optical receiver may be electrically coupled to an actuator. For example, the optical receiver may be directly electrically coupled to the actuator. In some embodiments, the first region at which an optical receiver is integrated in a compliant substrate may overlap with a second region at which an actuator is integrated in the compliant substrate, which may allow the optical receiver to pass an electrical signal to the actuator.

Furthermore, aspects of the disclosure may provide various method of manufacturing addressable actuators such as illustrated in FIG. 1. One exemplary method may include first forming a compliant substrate 102, such as an elastomer. Next, the method may include integrating the optical receiver 106 with a first region of the compliant substrate 102 and integrating the actuator 108 with a second region of the compliant substrate 102. During manufacturing, the optical receiver may be coupled to the actuator.

Further still, aspects of the disclosure provide method of operating addressable actuators such as illustrated in FIG. 1. The method may comprise receiving an optical signal using optical receiver 106 integrated with a first region of the compliant substrate 102. The method may then include in response actuating the actuator 108 integrated with a second region of the compliant substrate.

According to various aspects of the disclosure, percolating networks of photoconductive nanoparticles that are integrated with compliant substrates may be particularly well-suited for local addressing of DEAs for various reasons.

First, DEAs may operate at high voltages, such as several kilovolts. Accordingly, percolating networks of semiconducting nanoparticles may be used as electrical channels configured to withstand high applied voltages in an off state. The electrical channels formed of semiconducting nanoparticles described herein may meet this use case by having a high electrical breakdown strength of about 6 kV mm⁻¹ for percolating networks of zinc oxide nanowires.

Second, response time of percolating networks of semiconducting nanoparticles from an on-state to an off-state when a light is removed may be affected by an applied electric field across the channel. Operation of DEA devices may involve high electric field, and therefore, a higher electric field may provide a shorter switch-off time.

Third, DEA devices may be used in environments where mechanical compliance may be an important characteristic for functionality of the device. For example, DEAs may be used in soft and thin wearable devices for haptics displays. Such devices may use high mechanical compliance, which may be satisfied by low stiffness of percolating networks of the nanoparticles, as described herein.

Fourth, integration of the semiconductor nanoparticles provides designs of DEA-based devices by allowing devices to be formed without individual switches for local addressing of the DEAs, which may reduce complexities associated with creating individual connectors. In some embodiments, percolating networks for DEAs may be formed following a similar procedure used for forming arrays of electrodes, and may be controlled using projection of pattern lights. In various embodiments, design may not form electrical channels but may instead form photoswitchable electrodes configured to perform the task of both channels and electrodes.

Exemplary embodiments are now provided below. According to aspects of the disclosure, there are provided compliant actuators. In some embodiments, a compliant actuator may comprise a dielectric elastomer actuator (DEA). A DEA may comprise an electrically driven soft actuator configured to generate fast and reversible deformations and may generate the deformations with high power densities and efficiencies. DEAs may enable lightweight actuation in various soft robot or haptic device environments, as well as in other environments. In some embodiments, DEAs may use high voltage for operation. In some conventional systems, the high-voltage operation of DEAs combined with paucity of soft, small high-voltage microelectronics may limit the number of discrete DEAs that may be incorporated into a soft robot, haptic device, or other environment. Both the versatility and complexity of tasks that a compliant actuator system may perform may depend at least in part on the number of independently addressable actuating elements of the system. Therefore, conventional systems may be hindered in the versatility and complexity of the tasks that they may perform. Conventional systems may lack high-resolution spatial control of deformations.

Aspects of the disclosure provide new compliant actuator systems using optical addressing. For example, according to some embodiments, there is provided a new class of optically addressable dielectric elastomer actuators. In some embodiments, the actuators may utilize photoconductive materials, such as semiconducting zinc oxide nanowires, to create optically switchable and stretchable electrical channels. Optically addressable actuators may enable non-contact, optical control of local actuation of the actuators. Actuators according to the disclosure may be more versatile than conventional systems. Actuators described herein with integrated photoconductive materials are described herein. Further, the response of certain exemplary actuators is described, such as the response of dielectric elastomer actuators with integrated photoconductive channels, formed from thin films of percolating semiconducting nanoparticles.

Aspects of the disclosure further provide an array of optically addressable compliant actuators. A switchable array of light emitting diodes may be provided to optically address the array of actuators, and accordingly, actuation of the array may be controlled both spatially and temporally.

A major shortcoming of conventional systems using arrays of DEAs is the lack of adequate techniques for addressing and actuating individual actuators in the array, as each actuator is to be controlled separately. Among other effects on conventional systems, the lack of adequate addressing techniques poses challenges for creating shape changes. These challenges presented are further compounded because the number of connections used for an array increases with the number of actuators in the array and because the driving voltages of DEAs may be high.

According to aspects of the disclosure, there are provided integrated stretchable photoconductive electrical channels coupled to actuators. In some embodiments, the photoconductive electrical channels may comprise percolating networks of semiconducting nanowires, which may be integrated with the actuators during the fabrication of actuators and arrays thereof. After fabrication, the photoconductivity of the channels may be used to optically switch connections of the actuators. Integrating the photoconductive channels may simplify wiring of the actuators and may provide non-contact addressability of the actuator elements in an array. Simplified wiring and non-contact addressability may provide an array to having a larger number of independently controllable actuators and a greater number of independently controllable degrees of freedom.

In some embodiments, a DEA may comprise a soft capacitor including a thin elastomer layer coated by at least two compliant electrodes. In operation, a voltage may be applied between the electrodes. Upon applying the voltage, coulombic attraction of opposite charges on the compliant electrodes compresses the elastomer layer in thickness. As the electrode is compressed in a direction of the thickness, and the incompressibility of the elastomer provides an expansion of the elastomer along a lateral direction. Voltage-driven mechanical deformations of DEAs may be fast and reversible. The fast and reversible properties of DEA deformations may be used in various environments, including soft robotics and haptics devices.

Driving voltages of DEA devices may be on the order of several kilovolts and currents may be on the order of tens of micro amperes. The use of high voltages and low currents may not inherently present either drawbacks or safety issue. Rather, the use of high voltages and low currents may result in low ohmic losses, low charging and discharging time constants. However, the absence of small, high-voltage, soft microelectronics poses a challenge to conventional systems for addressing individual actuators in multiple-DEA arrays and devices.

In some systems, to address individual actuators, DEA-based devices may use commercially available high-voltage mechanical relays such as 5501 Dec. 1 Coto Relays MOSFETs such as IXTT02N450HV, or other relays that must be complexly interfaced with separately formed actuators. High-voltage mechanical relays, MOSFETs, and said other relays all present two major challenges. First, volume and weight of these elements can be greater than the actuators themselves, which scales up with the number of independently addressable actuators per volume. Second, creating interconnects between large numbers of addressing elements and actuators increasingly complicates fabrication processes. These two drawbacks may significantly limit the number of individually addressable actuators that may be provided in conventional systems of DEA-based devices, which limits the complexity of the attainable functions of these conventional systems.

Despite the lack of adequate high-voltage switches for conventional systems with multiple-DEAs arrays, some conventional systems may use separate switching circuits formed on a first substrate and then attached to DEAs on a second substrate. For instance, conventional systems may use an array of 4×4 high-voltage tin-oxide thin film transistors on a flexible polyimide substrate to control individual DEAs in an array of 4×4 actuators. Such a system may operate at voltages larger than 1 kV and 20 μA current, using gate voltages of 30 V, and may function when bent to a 5 mm radius of curvature. In some other conventional systems, high-voltage switches for DEAs are provided on a first substrate. The high-voltage switches may then be interfaced with a single DEA on a second substrate. In some conventional systems, an array of 2×3 photoconductive switches are formed on a first substrate and interfaced with an array of DEAs on a second substrate using a set of wires.

Conventional systems do not use channels and electrodes that are both stretchable for the purpose of addressing DEAs. According to some embodiments of the disclosure, there are provided percolating networks of semiconductor nanoparticles integrated with electrode designs, providing optically addressable DEAs configured to perform actuations with high special resolutions.

Aspects of the disclosure address drawbacks of conventional systems and provide fully integrated and embedded optical receivers, such as high-voltage photoconductive electrical channels, that are configured to provide non-contact optical addressing of individual actuators in compliant actuator arrays, such as DEA arrays. For example, photoconductive channels in some embodiments may be formed of percolating networks of photoconductive zinc oxide nanowires formed onto elastomer layers using a same method of forming stretchable electrodes of DEAs. Accordingly, aspects of the disclosure provide simple fabrication of DEA-based devices with multiple actuators and fully integrated photoswitches, that in some embodiments may be fabricated without any post-fabrication assembling.

In various embodiments, percolating networks of zinc oxide nanowires may be integrated into compliant substrates, such as soft elastomer matrices or other elastomer substrates, The integrated percolating networks may provide low mechanical stiffnesses and high stretchability, in contrast to zinc oxide nanowires themselves. The inventors have recognized that the photoconductivity of stretchable electrical channels of percolating networks of semiconducting nanoparticles may be applied to high-voltage applications or DEA and other actuator-based environments. The inventors have further recognized that percolating networks of zinc oxide nanowires are particularly suitable for addressing stretchable DEAs at high operating voltages. Embodiments of the disclosure describe properties of the percolating channels, actuation response of channels embedded into an elastomer, embodiments of channels used for actuating an exemplary 6×6 DEA array.

Although semiconductors may have high mechanical stiffnesses and low strains to rupture, percolating networks of semiconductors may show low mechanical stiffness and high stretchability. When a network of nanoparticles is stretch, individual and patches of nanoparticles may slide past each other, and therefore a mechanical stiffness of the network may come from small physical interactions and frictions between nanoparticle rather than a high stiffness between individual nanoparticles themselves.

According to various embodiments, there may be provided an n×m array of DEAs. In some embodiments, an array may include more than 10 actuators in one or both dimensions, more than 100 actuators in one or both dimensions, or more than 1000 actuators in one or both dimensions. The array may be formed using an array of n rectangular electrodes on one side of an elastomer layer and an array of m rectangular electrodes on the other side of the elastomer layer. The electrode arrays may be oriented perpendicular to each other. Multilayer arrays may be formed using the n and m arrays of electrodes on alternating layers of elastomer. The n×m array of DEAs may be addressed using n+m switches.

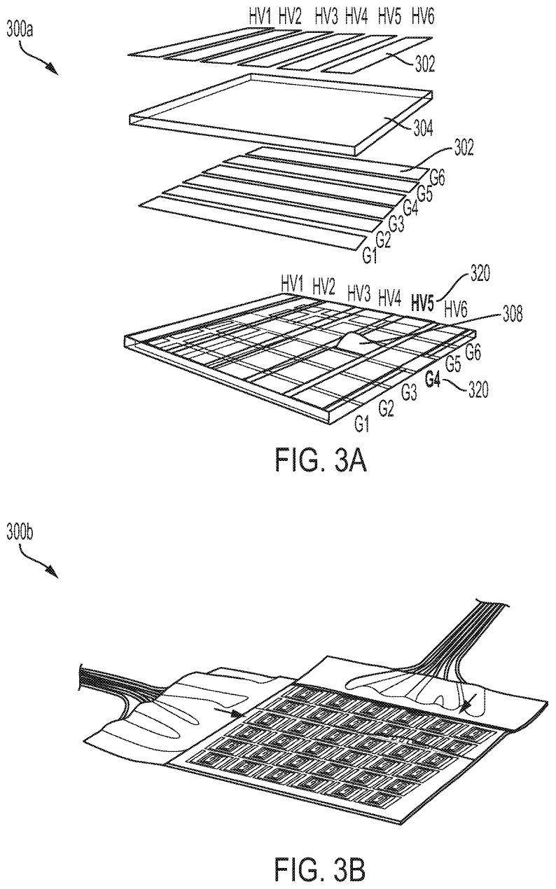

For example, FIGS. 3A and 3B show an exemplary embodiment of DEA array 300a and DEA array 300b. For example, FIG. 3A shows array 300a with arrays of electrodes 302, elastomer layer 304, with an actuated DEA 308 and addressed electrodes 320. FIG. 3A shows a schematic of an array 300a 6×6 DEAs, consisting of an elastomer layer with two arrays of 6 rectangular electrodes on each side. To actuate an individual DEA in the array 300a, one electrode on each side may be address, for example ground electrode G4 and high voltage electrode HV5. FIG. 3B shows an exemplary embodiment of a DEA array 300b. Array 300b may comprise 12 layers or elastomer sandwiching 10 layers of electrodes. In some embodiments, concentric squares may be 3D printed onto the bottom of each DEA to produce locally anisotropic deformations, and to break the symmetry along the thickness of the array, which may allow for producing out-of-plane deformations. The arrows indicate addressed electrodes.

Some embodiments relate to the physical basis of photoconductive channels consisting of percolating networks of semiconducting nanoparticles. In various embodiments, when the percolating networks are illuminated by photons form light with energies higher than a bandgap, nanoparticle of the network become conductive and, when nanoparticle densities are beyond a percolation threshold, networks of electrically conductive paths may be formed in the channels. A resistance of the network may comprise a sum of the resistance of the nanoparticles, which may be tunable based on light intensity, and the contact resistance between nanoparticles. When light is removed, the semiconducting nanoparticles, and therefore the percolating network, may become insulating again.

DEAs may be locally addressed with integrated semiconductors, and may be activated based on photocurrent of the semiconductors. In some embodiments, semiconductors such as undoped zinc oxide and cadmium sulfide, with bandgaps larger than 2 eV have nearly empty conduction bands and nearly full valence bands at room temperature, which may make them electrically insulating due to paucity of electrical carriers. Shining light with photon energies large than the bandgap of the semiconductor excites the electrons from the lower energy valence band into the higher energy conduction band, which may create electron carriers in the conduction band and hole carriers in the valence band. As a result, when illuminated with light of a specific range of wavelengths, the semiconductors may become electrically conductive and allow current flow under external voltages, for example, photocurrent. The density of the carriers and the conductivity of the semiconductor may be tuned by the intensity of the light. The tuning is reversible, for example, when light is removed, the electrons and holes may recombine, decreasing the number of electrical carries, and the semiconductor becomes electrically insulating again.

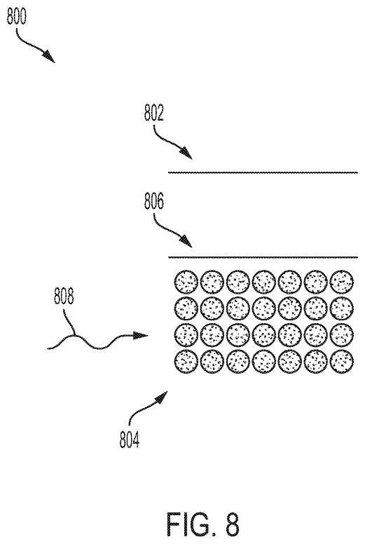

FIG. 8 shows an exemplary embodiment of a bandgap of a semiconductor material. Referring to FIG. 8, Zinc oxide nanowires 800 may have a valence band 802, a conduction band 804, and a direct bandgap 806, and may be illuminated by light 808. Zinc oxide nanowires may have a direct bandgap 806 of around 3.2 or 3.3 eV and may show photocurrent when illuminated by light 808 such as ultraviolet (UV) light with wavelengths smaller than about 375 nm, which may be light having a photon energy hv greater than about 3.2 or 3.3 eV (with h comprising Plank's constant and v comprising frequency of the light in hertz). Photoconductive response of the zine oxide nanowires may be mainly governed by oxygen adsorption and desorption in air. For example, oxygen atoms may chemisorb to zinc oxide nanowire surfaces and act as electron acceptors. When illuminated by UV light, holes in the photogenerated electron-hole pairs may interact with the negatively charged chemisorbed oxygen atoms and make them electrically neutral. These physiosorbed oxygen atoms can leave the surface as a result of thermal vibrations. This process lowers the electron-hole recombination rate, resulting in large numbers of excess electrons in the conduction band, having orders of magnitude higher mobility compared to the holes, and therefore large photocurrents. The photocurrent may increase with illumination time until the oxygen adsorption and desorption rates are balanced. As a result, larger photocurrents may be observed at lower oxygen pressures. When UV light is removed, the limited number of holes may limit the electron-hole recombination rate. Instead, oxygen atoms may be resorbed onto the zinc oxide surfaces in order to capture the excess electrons and reduce the photocurrent. As a result, slower photocurrent decay rates may be observed at lower oxygen pressures. A process of diffusion of oxygen atoms and resorption onto zinc oxide surfaces may be slower than oxygen desorption caused by interaction of photogenerated holes with charged oxygen atoms, and therefore the photocurrent decay time may be slower than the rise time. Both processes may be substantially slower than electron-hole recombination rate, which may result in photocurrent rise and decay times that are in the order of seconds to several minutes, compared to less than a nanosecond for electron-hole recombination. The photocurrent and the rise and decay rates are highly dependent on the environment of zinc oxide nanowires. For this reason, the following presents measurements of photocurrent of percolating networks of zinc oxide nanowires embedded into polyurethane acrylate dielectric elastomers, as functions of time, area density, applied bias voltage, and UV light intensity.

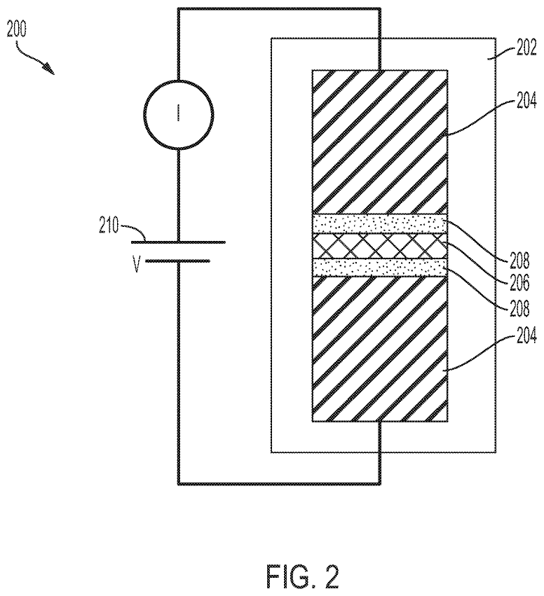

Aspects of the disclosure relate to photocurrent of embedded electrical channels of zinc oxide nanowires. Percolating networks of zinc oxide nanowires may provide photocurrent. FIG. 2 shows an exemplary embodiment of an optical receiver 200 comprising a compliant substrate 202, electrodes 204, photoconductive material 206, and overlap regions 208, and is coupled to a voltage source 210. In some embodiments, the optical receiver 200 comprises a compliant substate 202 formed of an elastomer, and the photoconductive material 206 comprises channels of percolating networks of zinc oxide nanowires. The channels are formed onto an elastomer substrate connecting two electrodes 204, each comprising an island of percolating networks of carbon nanotubes (CNTs). Overlap regions 208 comprise a region where the electrodes 204 overlap with the photoconductive material 206. The overlap may be provided to provide electrical connection of the electrodes 204 and the photoconductive material 206.

As shown in FIG. 2, to provide photocurrent of percolating networks of zinc oxide nanowires, two islands of percolating networks of carbon nanotubes (CNTs) are provided, with dimensions of 10 mm×10 mm, and 1 mm apart from each other. The islands may be connected using an electrical channel comprising zinc oxide nanowires. The width of the exemplary channel is W=10 mm, and the length of the channel is L=1 mm and there is 1 mm overlap with each of the two islands of CNTs, illustrated as overlap regions 208 in FIG. 2.

The elastomer substrate, and other compliant substrates described herein, may comprise a urethane acrylate precursor, that is spin coated, and cured using ultraviolet light. To fabricate an elastomer layer, the elastomer substrate may be formed of a urethane acrylate precursor, which may comprise 99.5% CN9028 (for example, from Sartomer Arkema Group) and 0.5% Diphenyl (2,4,6-trimethylbenzoyl) phosphine oxide (for example, from Sigma-Aldrich) as the photoinitiator. The precursor may be spin coated at about 3000 rpm for about 1 min and cured using ultraviolet light and nitrogen-filled environment for about 100 s.

Percolating networks of zinc oxide nanowires may be formed using a similar method as the CNT electrodes. For example, first, zinc oxide nanowires may be suspended in isopropanol using ultrasonication, for example, about 80 mg of zinc oxide nanowires may be suspended in about 80 g of isopropanol using ultrasonication for about 8 min at about 80% power (for example, using a Branson 450 Digital Sonifier attached to a one-half inch tapped stepped disruptor horn through a 102C convertor). Next, about 4.0 g of the dispersion may be vacuum filtered through a porous filter with 0.2 mm pore sizes (for example, T020A090C, Advantec, Dublin, CA), which may form percolating networks of zinc oxide nanowires with density of 1.0 mg mm⁻¹. Then, the photoconductive electrical channels may be formed by stamping the filters onto elastomer substrates. Shapes and dimensions of channels may be formed by disposing masks between the elastomer and the filter, and the masks may be cut from a clear silicone release film, for example using a desktop cutting machine (for example, CRP41082, Drytac, Richmond, VA). Masks and stamps may then be removed, and an encapsulating layer of elastomer may be formed on top of the CNT electrodes and zinc oxide channel, using a similar material and method as for the substrate.

CNT electrodes may be formed by vacuum filtration of a dispersion of CNTs in deionized water through a porous filter, which may be stamped onto an elastomer substrate. In other embodiments, electrodes may be formed of a same material as the photoconductive channels. In some embodiments, electrodes may be reconfigurable during operation. For example, the size and number of electrodes may be reconfigurable during operation. In some embodiments, the electrodes may be formed of zinc oxide nanowires, which may enable the size and number of electrodes to be selected during operating. For example, during operation, a light emitting device may shine light on one or more regions corresponding to the desired size of a desired number of reconfigured electrodes. The reconfigurability of electrodes may be provided in embodiments where the electrodes and photoconductive channels are formed of a same material.

Though methods of forming actuators are described above, these methods should not be understood to be limiting. Rather, these methods illustrate merely some exemplary methods. In various embodiments, compliant substrates and layers, optical receivers including photoconductive channels, actuators including electrodes, and other components described herein may be formed in any appropriate manner.

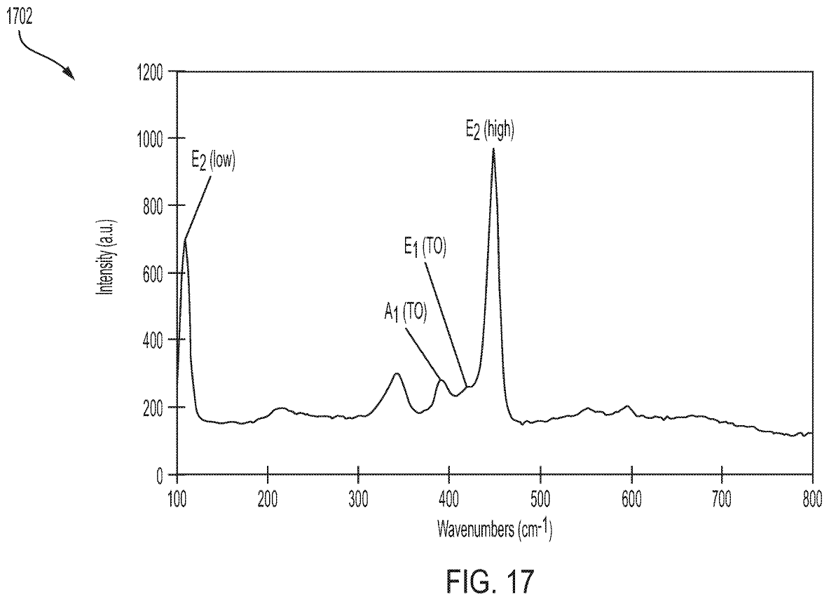

In various embodiments, zinc oxide nanowires may have a diameter of about 50 nm to 150 nm and length of about 5 mm to 50 mm. For example, exemplary zinc oxide nanowires may comprise SKU: NWZO01A5, ACS Material LLC. Raman spectrum of the exemplary zinc oxide nanowires is illustrated in FIG. 17. Referring to FIG. 17, a plot 1702 of Raman spectrum is provided, obtained for the zinc oxide nanowires powders on silicon wafer substrate using excitation from a 532 nm laser.

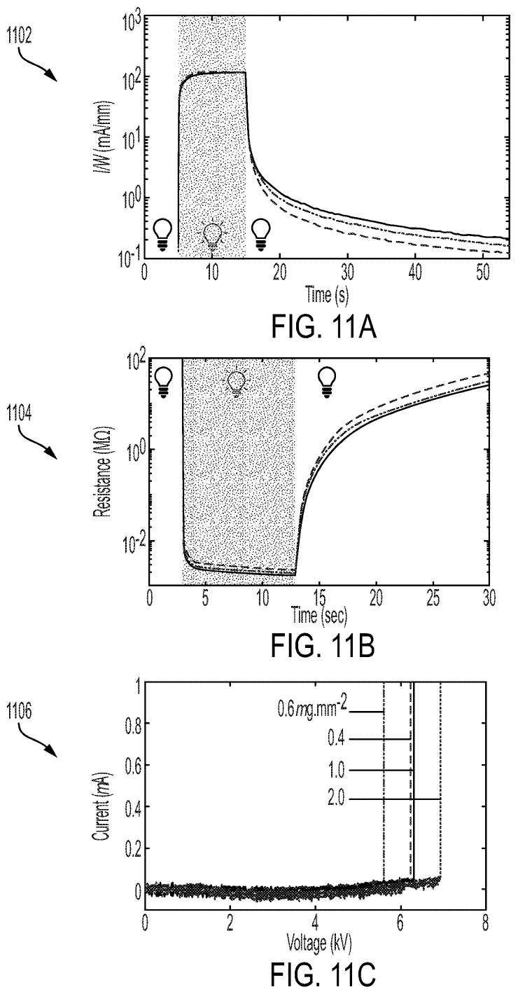

Photocurrents of the exemplary channels in FIG. 2 are provided and may be measured by applying bias voltages to the two ends of the CNT islands while measuring the current. FIG. 11A shows plot 1102 showing current per width with respect to time and FIG. 11B shows plot 1104 showing resistance with respect to time for the exemplary channels of FIG. 2.

In the exemplary embodiment, when a voltage source applies a bias voltage of 200 V to the two ends of the CNT islands and the channel illuminated by an array of seven UV light emitting diodes (LEDs) with peak wavelength of 365 nm (for example, ATS2012UV365, Kingbright) and light intensity of 3.41 mW mm⁻², FIG. 11A at t=5 s, the current through the channel jumped by nearly three orders of magnitude in just a second. This was then followed by a gradual increase over the next nine seconds while the UV light is on. When the UV light was removed, FIG. 11A at t=15 s, the current dropped by one order of magnitude in less than a second and gradually decreased towards zero over tens of seconds. FIG. 11B shows a related plot with resistance with respect to time for the same exemplary embodiment. Different lines show repeatability of three respective runs.

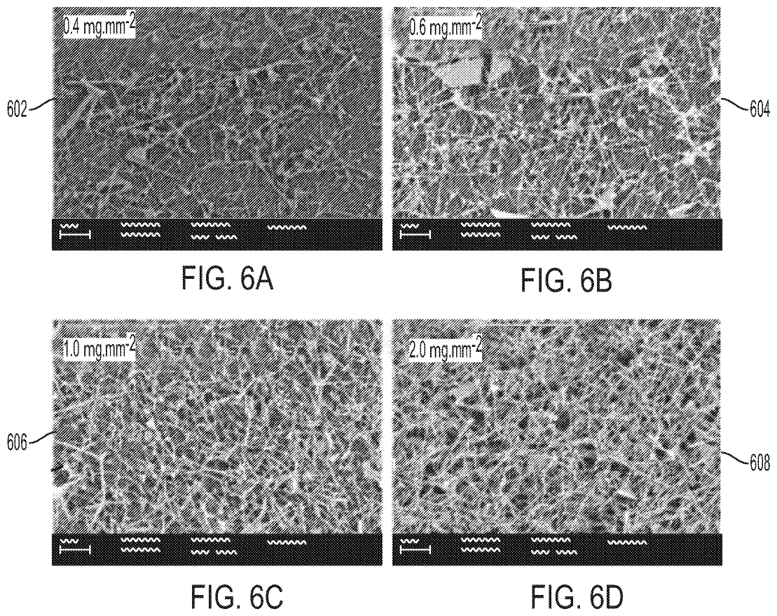

In various embodiments, photocurrents of zinc oxide channels may be provided based on the geometrical dimensions of a channel, density of the zinc oxide nanowires, applied bias voltage, and incident light. According to aspects of the disclosure, each of these parameters may have an effect on the photocurrent of percolating networks of zinc oxide nanowires. Channels with various zinc oxide densities may be used in optical receivers. As shown in FIGS. 6A-6D, channels with zinc oxide densities of 0.4, 0.6, 1.0, and 2.0 μg mm⁻² may be fabricated by vacuum filtration and stamping of 1.6, 2.4, 4.0 and 8.0 g of zinc oxide nanowire dispersion, respectively. FIG. 6A shows a channel 602 with a zinc oxide density of 0.4 μg mm⁻², FIG. 6B shows a channel 604 with a zinc oxide density of 0.6 μg mm⁻², FIG. 6C shows a channel 606 with a zinc oxide density of 1.0 μg mm⁻², and FIG. 6D shows a channel 608 with a zinc oxide density of 2.0 μg mm⁻². FIGS. 6A-6D show scanning electron microscopy (SEM) images of the percolating networks of zinc oxide nanowires.

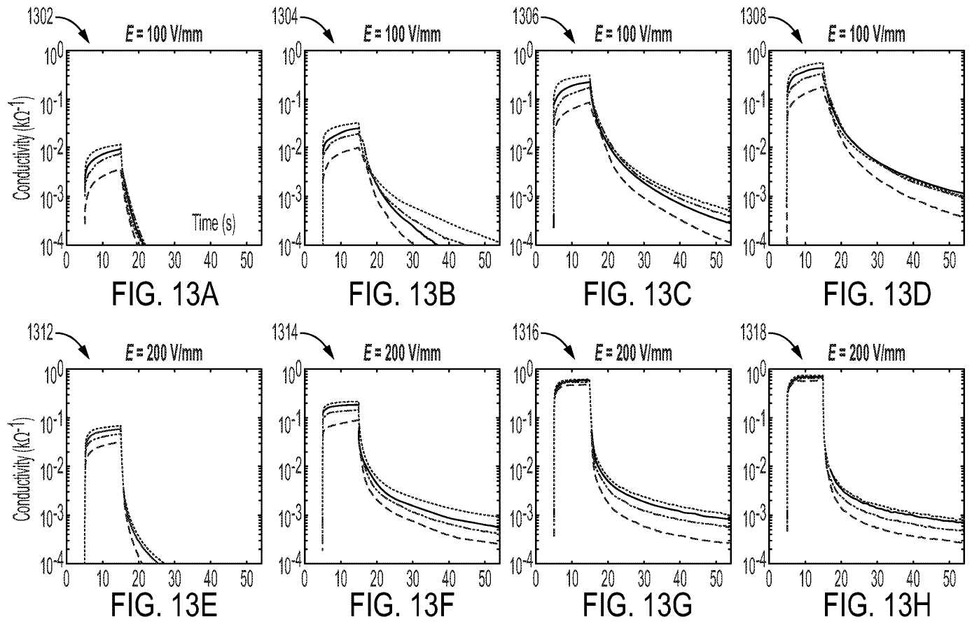

Photocurrents of channels having different zinc oxide densities are provided herein. For example, in exemplary embodiments, for channels with zinc oxide densities of 0.4, 0.6, 1.0, and 2.0 μg mm2, photocurrents of the channels may be measured under bias voltages of 100 and 200 V and UV light intensities of 2.27, 3.41, 4.55, 5.69 mW mm⁻². For the exemplary zinc oxide densities of 0.4, 0.6, 1.0, and 2.0 μg mm⁻² in FIG. 6A-6D, measurements for of the percolating networks of zinc oxide nanowires are shown in FIGS. 13A-13H. FIG. 13A shows a plot 1302 for channel 602, FIG. 13B shows a plot 1304 for channel 604, FIG. 13C shows a plot 1306 for channel 606, FIG. 13D shows a plot 1308 for channel 608, each showing photoconductivity as a function of time, under a bias voltage of 100 V. Moreover, FIG. 13E shows a plot 1312 for channel 602, FIG. 13F shows a plot 1314 for channel 604, FIG. 13G shows a plot 1316 for channel 606, FIG. 13H shows a plot 1318 for channel 608, each showing photoconductivity as a function of time, under a bias voltage of 200 V. UV light intensities of 2.27, 3.41, 4.55, 5.69 mW mm⁻² are shown in each of FIGS. 13A-13H, with 2.27 mW mm⁻² being the lowermost curve, 3.42 mW mm⁻² being the second lowermost curve, 4.55 mW mm⁻² being the second uppermost curve, and 5.69 mW mm⁻²being the uppermost curve, respectively in each plot.

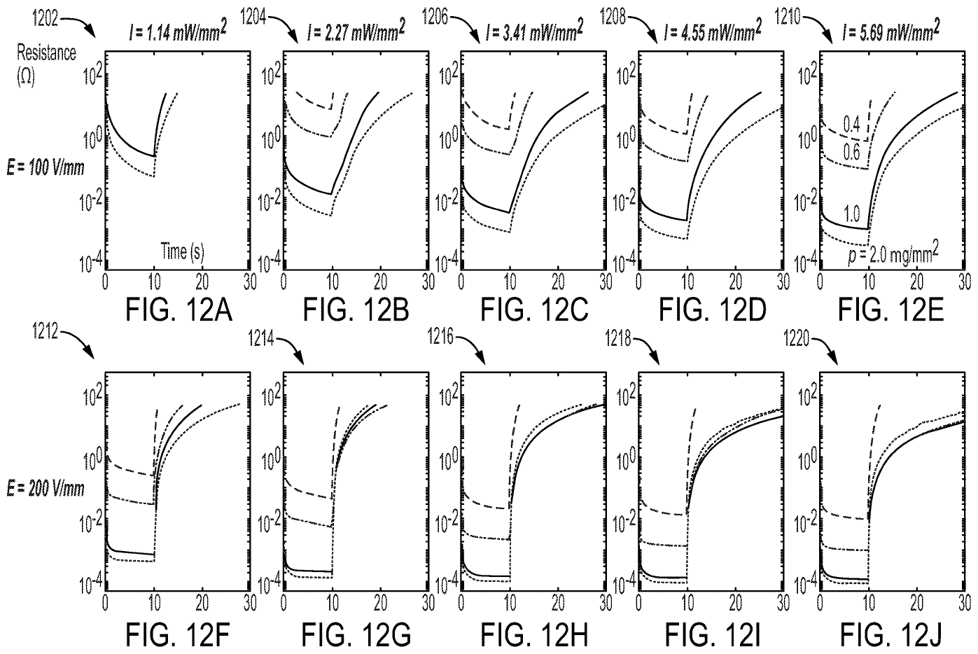

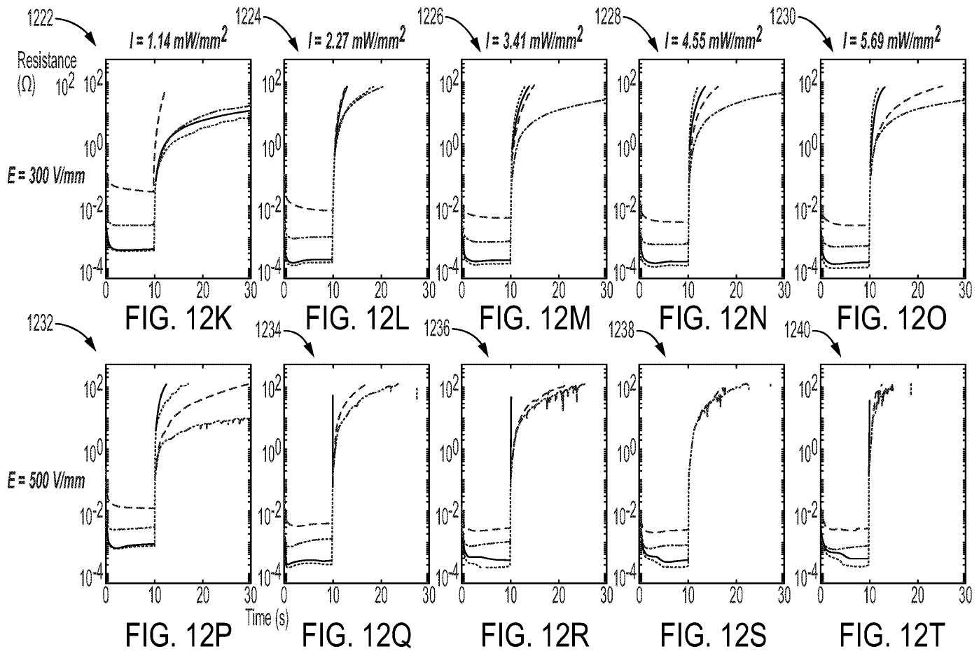

FIGS. 12A-12T may further show resistance with respect to time for zinc oxide areal densities of 0.4, 0.6, 1.0, and 2.0 μg mm⁻², at light intensities of 1.14, 2.27, 3.41, 4.55, and 5.69 mW mm⁻², and at electric fields of 100, 200, 300, and 500 V mm⁻¹. To provide the plots of FIGS. 12A-12T, channels may be activated using an array of 7 UV LEDs (for example, ATS2012UV365, Kingsbright), which may have their peak light intensity at about 360 to 360 nm wavelength. As shown in FIGS. 12A-12T, electrical resistance of channels may drop by more than four orders of magnitude and recover when light is turned off. The characteristic times for the resistance and recover and the resistance when the light is on may depend on the intensity of incident light, density of the semiconductive nanowires, and an applied voltage.

For each of FIGS. 12A-12T the uppermost curve represents a density of 0.4 82 g mm⁻², the second uppermost curve represents a density of 0.6 μg mm⁻², the second lowermost curve represents a density of 1.0 μg mm⁻², and the lowermost curve represents a density of 2.0 μg mm⁻², though FIG. 12A is truncated and does not show densities of 0.4 and 0.6 82 g mm⁻². FIG. 12A shows a plot 1202 for light intensity 1.14 mW mm⁻², FIG. 12B shows a plot 1204 for light intensity 2.27 mW mm⁻², FIG. 12C shows a plot 1206 for light intensity 3.41 mW mm⁻², FIG. 12D shows a plot 1208 for light intensity 4.55 mW mm⁻², and FIG. 12E shows a plot 1210 for light intensity 5.69 mW mm⁻², each at electric field 100 V mm⁻¹. FIG. 12F shows a plot 1212 for light intensity 1.14 mW mm⁻², FIG. 12G shows a plot 1214 for light intensity 2.27 mW mm⁻², FIG. 12H shows a plot 1216 for light intensity 3.41 mW mm⁻², FIG. 12I shows a plot 1218 for light intensity 4.55 mW mm⁻², and FIG. 12J shows a plot 1220 for light intensity 5.69 mW mm⁻², each at electric field 200 V mm⁻¹. FIG. 12K shows a plot 1222 for light intensity 1.14 mW mm⁻², FIG. 12L shows a plot 1224 for light intensity 2.27 mW mm⁻², FIG. 12M shows a plot 1226 for light intensity 3.41 mW mm⁻², FIG. 12N shows a plot 1228 for light intensity 4.55 mW mm⁻², and FIG. 120 shows a plot 1230 for light intensity 5.69 mW mm⁻², each at electric field 300 V mm⁻¹. FIG. 12P shows a plot 1232 for light intensity 1.14 mW mm⁻², FIG. 12Q shows a plot 1234 for light intensity 2.27 mW mm⁻², FIG. 12R shows a plot 1236 for light intensity 3.41 mW mm⁻², FIG. 12S shows a plot 1238 for light intensity 4.55 mW mm⁻², and FIG. 12T shows a plot 1240 for light intensity 5.69 mW mm⁻², each at electric field 500 V mm⁻¹. As shown in FIGS. 12A-12T, channel resistance under UV light may decrease with increasing light intensity, zinc oxide areal density, and applied voltage.

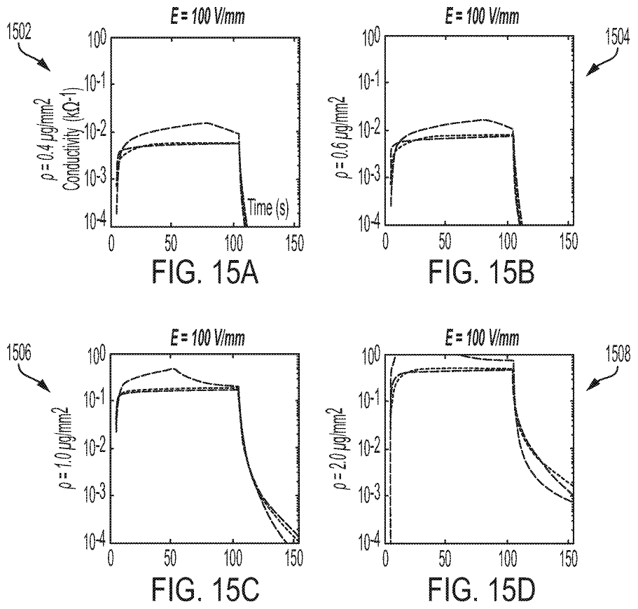

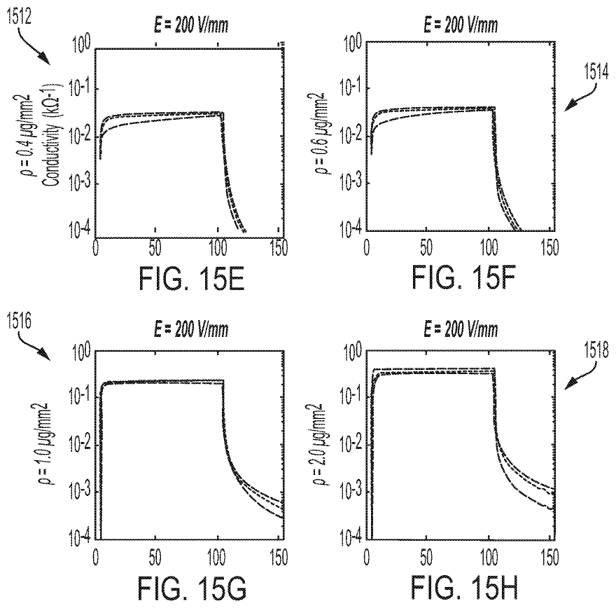

Conductivities, s, for the channels may be calculated from the applied bias voltage, V, measured current, I, and channel dimensions, W and L, with s=IL/VW. When UV exposure time is increased from 10 s to 100 s, transient effects may be observed during the first exposure followed by repeatable photocurrents during the following ones, such as in FIGS. 15A-15H. FIGS. 15A-15H show photoconductivity of zinc oxide nanowires channels under 100 seconds of UV exposure with 3.41 mW mm⁻² intensity, and 100 and 200 V bias voltages for the zinc oxide nanowires densities of 0.4, 0.6, 1.0, and 2.0 μg mm⁻². FIG. 15A shows a plot 1502 for channel 602, FIG. 15B shows a plot 1504 for channel 604, FIG. 15C shows a plot 1506 for channel 606, FIG. 15D shows a plot 1508 for channel 608, each showing photoconductivity as a function of time, under a bias voltage of 100 V, with 3.41 mW mm⁻²intensity. Moreover, FIG. 15E shows a plot 1512 for channel 602, FIG. 15F shows a plot 1514 for channel 604, FIG. 15G shows a plot 1516 for channel 606, FIG. 15H shows a plot 1518 for channel 608, each showing photoconductivity as a function of time, under a bias voltage of 200 V, with 3.41 mW mm⁻² intensity. Respective curves on each plot represent four different cycles.

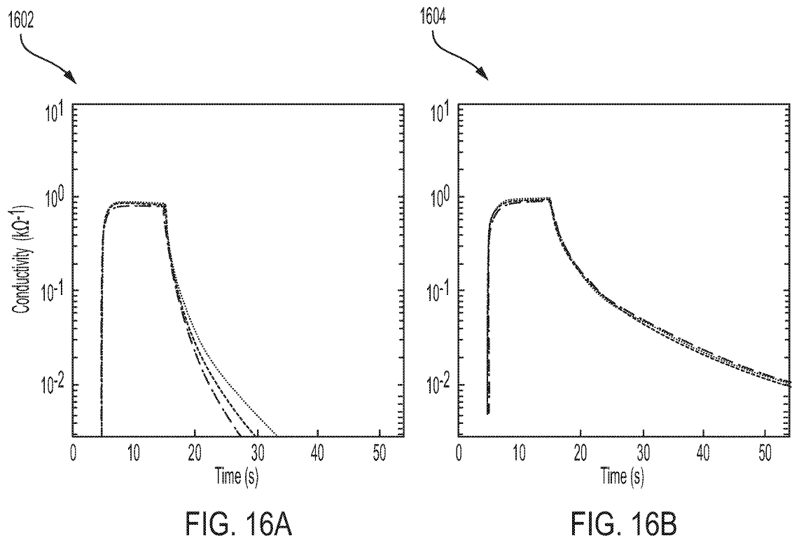

Stability of the zinc oxide nanowires after 10 min UV exposure while the bias voltage is off is provided herein. For example, FIGS. 16A-16B show photocurrent of a zinc oxide nanowires channel with 1.0 82 g mm⁻² density (for example, such as channel 606) without a top encapsulating elastomer layer and exposed to air under 10 seconds of UV exposure with 3.41 mW mm⁻² intensity and 100 V bias voltage. FIG. 16A show a plot 1602 for before 10 minutes of UV exposures in the absence of the bias voltage, and FIG. 16B shows a plot 1604 for after 10 minutes of UV exposures in the absence of the bias voltage.

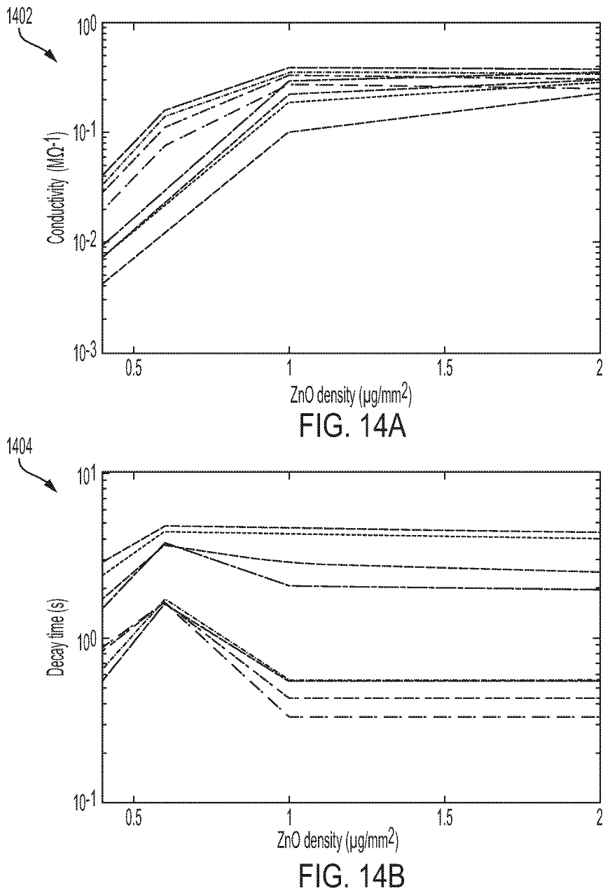

FIG. 14A shows a plot 1402 for maximum photoconductivity while a UV light is on. FIG. 14B shows a plot 1404 for a decay time for the conductivity to drop by one order of magnitude when a UV light is turned off. FIGS. 14A are illustrated as functions of the zinc oxide nanowires density, under bias voltages of 100 and 200 V. Dashed lines represent bias voltages of 100 V and solid lines represent 200 V. Within the groups of dashed and solid lines of FIG. 14A and the group of solid lines for FIG. 14B, UV light intensities are illustrated as follows: a lowermost line shows of 2.27 mW mm⁻², a second lowermost line shows 3.41 mW mm⁻², a second uppermost line shows 4.55 mW mm⁻², and an uppermost line shows 5.69 mW mm⁻². Within the groups of dashed lines of FIG. 14B, UV light intensities are illustrated as follows: an uppermost line shows of 2.27 mW mm⁻², a second uppermost line shows 3.41 mW mm⁻², a second lowermost line shows 4.55 mW mm⁻², and a lowermost line shows 5.69 mW mm⁻².

Increasing density of the zinc oxide nanowires, for example, from 0.4 to 1.0 μg mm⁻², as for channels 602, 604, and 606, may increase the photoconductivity, as shown in plot 1402 of FIG. 14A. In some exemplary embodiments, reduction in resistance when the density was increased beyond a particular density threshold, for example, to 2.0 g μm⁻² for channel 608, may be less substantial. Referring back to the SEM images of FIGS. 6A-6D, at density of 2.0 μg mm⁻², beyond a particular density threshold, nanowires may start to accumulate on top of each other, which may shadow nanowires underneath and may therefore resulting in smaller photocurrent through these shadowed nanowires.

Increasing the applied bias voltage from 100 V to 200 V may result in higher photoconductivity and faster switching, comparing the dashed and solid lines in FIGS. 14A and 14B, respectively. Therefore, when used to address DEAs that normally operate at few kilovolts, the channels of zinc oxide nanowires may exhibit both faster switching and larger photoconductivity.

Increasing the UV light intensity may reduce the UV-on resistance comparing the curves at UV light intensities of 2.27, 3.41, 4.55, 5.69 mW mm⁻² in FIG. 14A. Accordingly, channels of zinc oxide nanowires may not only act as high voltage electrical switches but may also tune a voltage drop, which may be controlled based on incident UV light intensity.

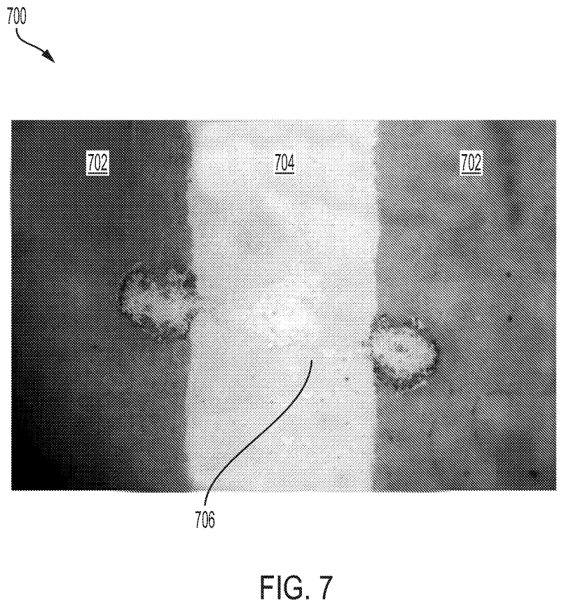

Aspects of the disclosure relate to electrical breakdown strength of channels of zinc oxide nanowires. FIG. 11C and FIG. 7 shows electrical breakdown of channels of percolating networks of zinc oxide nanowires. FIG. 11C shows a plot 1106 for channels with zinc oxide nanowire densities of 0.4-2.0 μg mm⁻², which show no measurable current in the absence of the UV light, until a sudden jump in current occurs because of electrical breakdown at about 6 kVmm⁻¹. In some embodiments, there may be no correlation with the zinc oxide nanowire density. FIG. 7 shows an optical microscope image of the electrical breakdown path through a channel 700, which may be a zinc oxide channel with density of 0.6 μg mm⁻². Physical damage to the exemplary channel is shown in FIG. 7, with the exemplary channel 700 comprising electrodes 702, which may be formed of CNT, optical receiver 704, which may be formed of zinc oxide. The channel 700 shows electrical breakdown 706. There may be crater-like damage produced by the electrical breakdown. In some embodiments, when channels of zinc oxide nanowires are used to address DEAs or other actuators, the channels may withstand large bias voltages and allow minimal leakage currents when there is no UV illumination. Accordingly, leakage current and electrical breakdown strength of channels of zinc oxide nanowires of with densities of 0.4, 0.6, 1.0, and 2.0 μg mm⁻², such as the channels 602, 604, 606, and 608 of FIGS. 6A-6D, are provided herein. Leakage current and electrical breakdown strength was measured for exemplary channels in the absence of UV light, shown in plot 1106 of FIG. 11C. For the exemplary embodiment, the zinc oxide channel showed no measurable current until the applied voltage reached about 6 kV, at which electrical breakdown occurred along the zinc oxide channel, indicated by a jump in current shown in FIG. 11C. In some embodiments, there may be no or little correlation between electrical breakdown strength and the density of zinc oxide nanowires, and leakage current may remain below a minimum measurable current of 0.06 pA for channels of all four densities until breakdown. Channels may demonstrate a high electrical breakdown strength of about 6 kV per mm of channel length, even when high densities of zinc oxide nanowires are used. The high electrical breakdown strength of the channels may be particularly important for addressing DEAs or other actuators that normally operate at a few kilovolts. In some embodiments, the electrical breakdown of a percolating network of zinc oxide nanowires may provide a minimum length of the channel and therefore size scaling of the devices incorporating the channels. In some embodiments, for a DEA device operating at 3 kV, a channel may be at least 0.5 mm long to stay below the breakdown condition.

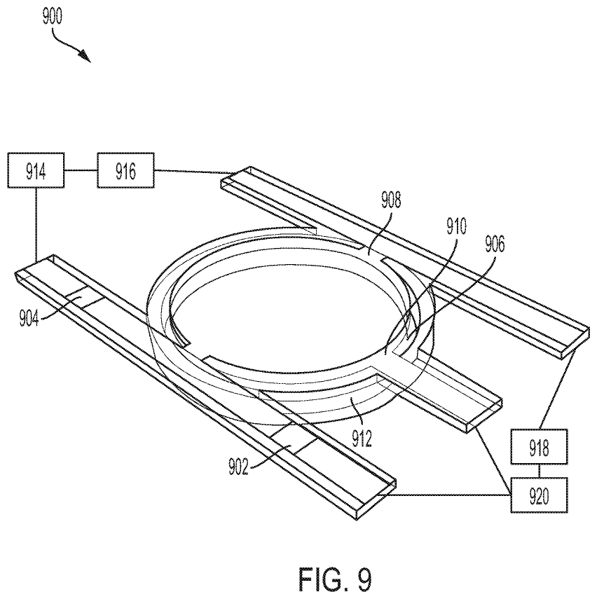

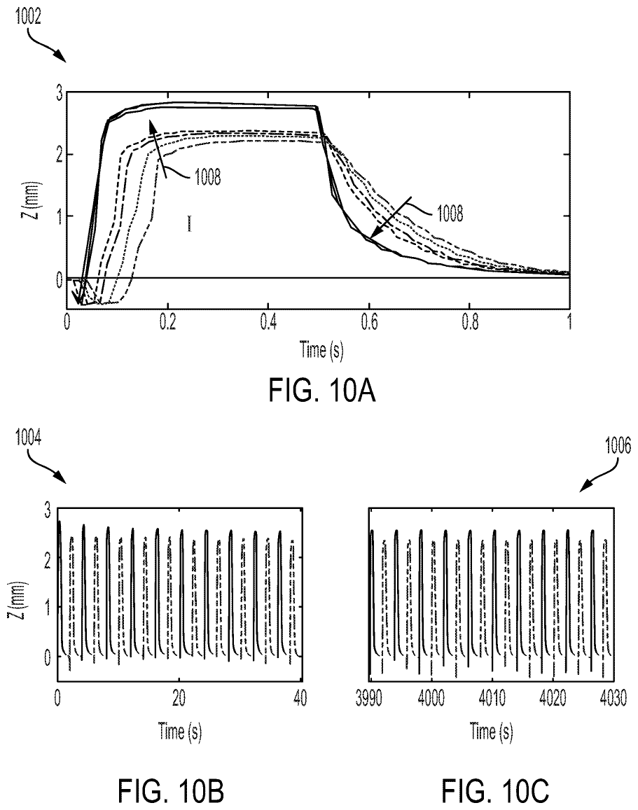

Aspects of the disclosure relate to actuation time response of DEAs with embedded zinc oxide nanowires channels. Characterization of actuation of DEAs addressed by zinc oxide nanowire channels is shown below. FIGS. 9 and 10A-10C show actuation of an exemplary actuator, for example, a multilayer DEA with zinc oxide nanowire channels.

The exemplary actuator 900 is shown in FIG. 9, and characterization of actuation of the actuator 900 is provided. The actuator 900 comprises a compliant layer 906, which may comprise multiple elastomer layers, at least one electrode 908, which may comprise high voltage electrodes, at least one electrode 910, which may comprise ground electrodes, and optical receivers 902 and 904, which may comprise first and second zinc oxide channels, respectively. In some embodiments, the actuator 900 may comprise ten active elastomer layers, 25 mm in diameter with 0.6 mm in total thickness, with eleven interdigitated high-voltage and ground CNT electrodes, though only one of each of electrode 908 and electrode 910 is shown in FIG. 9 for clarity of illustration. In some embodiments, the fabrication methods of the compliant layers, electrodes, and optical receivers may be fabricated by similar methods and of similar materials as elastomer layers, CNT electrodes, and zinc oxide channels described above.

The exemplary actuator 900 may be mounted in a frame 912 to simplify actuation measurements. The frame may be a circular frame and may force the actuator 900 to move out of the plane. For the exemplary embodiments, the out-of-plane displacement may be measured using a laser line scanner (for example, MTI ProTrak, PT-G 60-40-58). The ground electrode of the DEA may be connected to a ground terminal 920 of the power supply (for example, Trek 610E, Advanced Energy) and the high voltage electrode of the DEA may be either connected to the high voltage terminal 914 (for example, at 1.5 kV). The high voltage electrode may alternatively be connected to the ground terminal 920 of the power supply using either the zinc oxide nanowire channels (which may have a density of 1.0 μg mm⁻² density) or using relays 916 and 918, which may comprise photocell solid-state relays (for example, AQV258A, Panasonic). The photocell relay may provide a switching response with negligible leakage current and response time compared to the DEA.

FIG. 10A shows a plot 1102 for time response of the DEA at 1 Hz using solid-state relays, with the upper two curves black lines, and using zinc oxide channels for the lower group of four curves, with light intensities of 2.27, 3.41, 4.55, 5.69 mW mm⁻². The lowermost curve of the group shows response for 2.27 mW mm⁻², the second lowermost curve of the group shows response for 3.41 mW mm⁻², the second uppermost curve of the group shows response for 4.55 mW mm⁻², and the uppermost curve of the group shows response for 5.69 mW mm⁻². Arrows 1008 superimposed on plot 1002 show increasing light intensity. FIG. 10B shows a plot 1004 for the first actuation cycles of the DEA, and FIG. 10C shows the last ten actuation cycles of the DEA, when actuated for 1000 cycles alternating between the solid-state relays and zinc oxide nanowire channels, with the odd occurring curves showing the solid-state relays, and the even occurring curves showing the zine oxide nanowire channels.

When the relay 918 of FIG. 9 connects the high-voltage electrode of the DEA to the high-voltage terminal of the power supply, the DEA may buckle out of plane in less than 100 ms after the in-plane stress reach the threshold for out-of-plane buckling in less than 40 ms. The time response of the out-of-plane actuation, Z, is shown with the upper two curves of FIG. 10B. The out-of-plane buckling in the downward direction (negative Z) may be restricted using a stiff block placed about 0.5 mm below the actuator. When relay 918 is turned off and relay 916 is turned on, connecting the high-voltage electrode of the DEA to the ground terminal of the power supply, the actuator may move back to its original flat configuration, but with slower time response as compared to the actuation rate: the out-of-plane deformation may retract by about 0.7 mm, 50 ms after relay 916 was turned on, compared with the actuation of 2.5 mm, 50 ms after its out-of-plane buckling threshold was reached when relay 918 was turned on.

Actuator 900 may be addressed using optical receivers. For example, to address the DEA using zinc oxide nanowires channels, optical receiver 902 of FIG. 9 may be illuminated using two UV LEDs placed onto the channel, which may connect the high-voltage electrode of the DEA to the high-voltage terminal of the power supply. To remove the actuation, the

UV illumination of optical receiver 902 may be turned off and the optical receiver 904 may be illuminated with two UV LEDs, connecting the high-voltage electrode of the DEA to the ground terminal of the power supply. Out-of-plane actuation time response of the DEA when addressed using zinc oxide nanowire channels is shown with the lower group of four curves in FIG. 10B for illuminated UV light intensities of 2.27, 3.41, 4.55, 5.69 mW mm⁻², as described above respectively.

In some embodiments, time to reach a threshold for out-of-plane buckling may be higher for zinc oxide nanowires channels, compared to that of solid-state relays. In some embodiments, the time to reach the threshold may reduce with increasing the light intensity, ranging from 130 ms for 2.27 mW mm⁻² to 60 ms for 5.69 mW mm⁻². In some embodiments, actuation magnitude of a DEA may increase slightly with light intensity, ranging from 2.22 for 2.27 mW mm⁻² to 2.37 mm for 5.69 mW mm⁻², compared to about 2.8 mm when actuated using solid-state relays, which may be about 15% to 21% less. When optical receiver 904 is illuminated and optical receiver 902 is turned off, higher light intensity may also result in faster time response. For example, 100 ms after the optical receiver 904 is turned on, the actuation may drop to 1.1 to 1.5 mm for light intensities of 2.27 to 5.69 mW mm⁻², respectively, different from 0.5 mm for solid-state relay. In some embodiments, after 500 ms the difference may reduce to less than 0.1 mm. Accordingly, embedded percolating networks of zinc oxide nanowires or other integrated optical receivers may be provided as integrated high-voltage switches for non-contact optical addressing of DEAs or other actuators. In some embodiments, the zinc oxide nanowires, at 1 Hz, may have an actuation displacement that is 15-20% reduced, and which may be further decreased with actuation frequency.

FIGS. 10B and 10C show cycles alternating between using solid-state relays and zinc oxide channels, with odd occurring cycles for the solid-state relays and even occurring cycles for the zinc oxide channels. Cycling tests may be performed for an exemplary DEA when addressed using the solid-state relays and zinc oxide channels. For the zinc oxide channels, they may be illuminated UV light intensity of 2.27 mW mm⁻². FIGS. 10B and 10C illustrate a test of 1000 cycles and shows that actuation magnitudes and response times for the first ten cycles (FIG. 10B) are similar as for the last ten cycles (FIG. 10C). Accordingly, DEAs with zinc oxide nanowires may provide robust performance over large numbers of cycles.

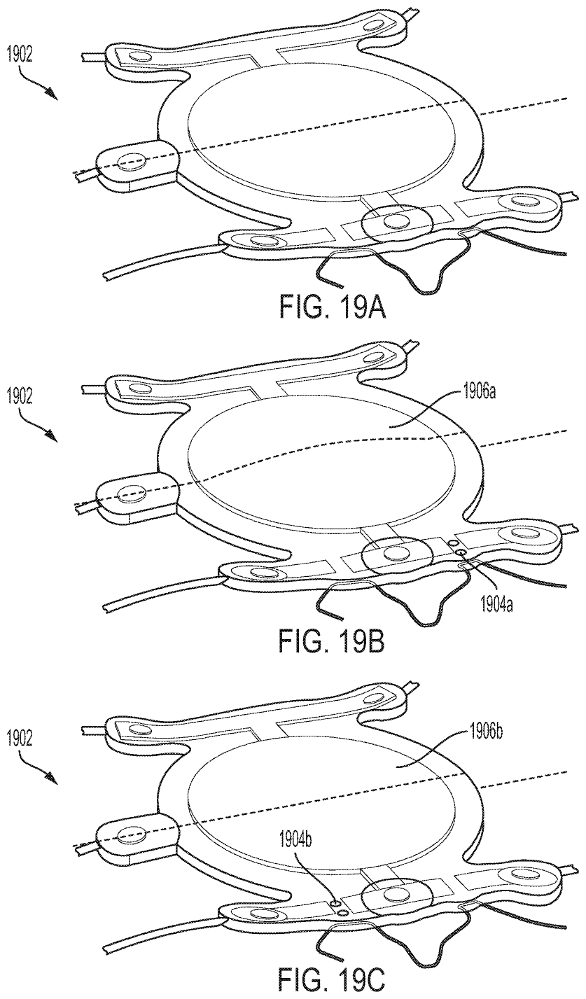

An exemplary cyclic actuation of a DEA such as actuator 900, using zinc oxide nanowires channels is shown in FIGS. 19C. FIG. 19C shows actuator 1902, which comprises a first coupled light source and optical receiver 1904a and a second coupled light source and optical receiver 1904b. In FIG. 19A, actuator 1902 has no deformation. In FIG. 19B, the first light source provides a light signal to the first optical receiver, and the second light source does not provide a light signal to the second optical receiver, and the actuator 1902 has a deformation 1906a. In FIG. 19C, the first light source does not provide a light signal to the first optical receiver, and the second light source provides a light signal to the second optical receiver, and the actuator 1902 has a deformation 1906b, which may an undeformed state of the actuator 1902.

To actuate a dielectric elastomer actuator using solid state relays or embedded electrical channels of percolating networks of zinc oxide nanowires, the ground electrode of the DEA may be connected to the ground terminal of the power supply. An exemplary actuation sequence may be as follows: the actuator is first activated for 500 ms using a solid-state relay, connecting the high-voltage electrode of the DEA to the high-voltage terminal of the power supply at 1.5 kV. The first relay may be turned off and the actuation is removed by activating the second relay for 500 ms, connecting the high-voltage electrode of the DEA to the ground terminal of the power supply. After 1000 ms the process may be repeated but this time using the zinc oxide nanowire channels: first set of LEDs may be turned on activating the first zinc oxide nanowire channel for 500 ms, followed by activating the second zinc oxide nanowire channel for 500 ms using the second set of LEDs. A projected laser line in may be used to measure the out of plane displacement of the DEAs.

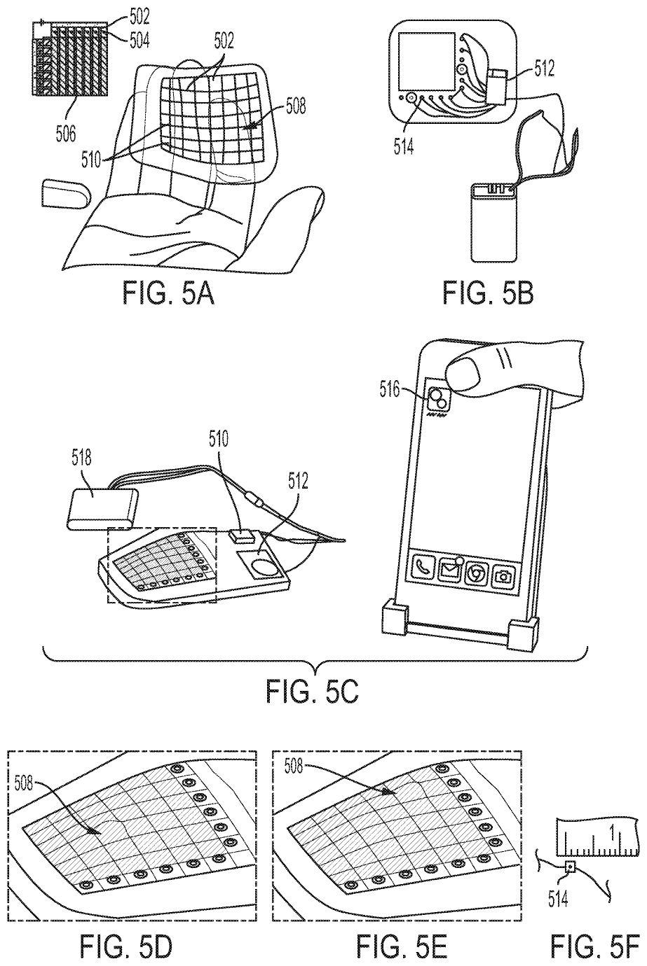

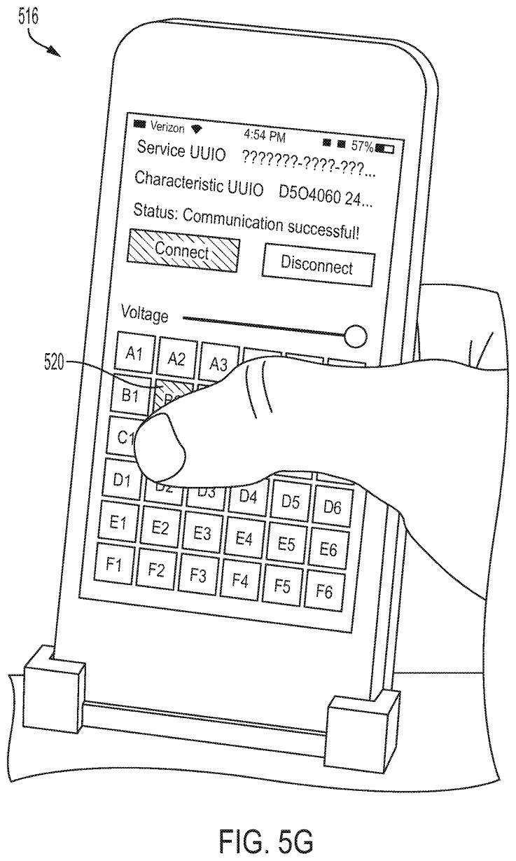

Aspects of the disclosure relate to addressing arrays of DEAs other actuators using integrated optical receivers, such as channels of zinc oxide nanowires. FIGS. 5A-5G show an exemplary embodiment of a system including an actuator and a light emitting device. As shown in the exemplary embodiment, new design space is enabled by integrating percolating networks of zinc oxide nanowires into DEAs. Systems such as the system illustrated in FIGS. 5A-5G may provide local actuations of a sheet of DEAs, which may be optically addressed using channels of zinc oxide nanowires.

FIGS. 5A-5G show an exemplary embodiment of an optically addressable DEA array with integrated channels of zinc oxide nanowires. FIG. 5A photoconductive channels 502, vias 504, arrays of CNT electrodes 506, a DEA array 508, and a power supply 510. As shown in FIG. 5A, the array 508 comprising 6×6 multilayer DEAs may be connected to positive and negative terminals of the power supply 510 through two sets of 6 channels 502 of zinc oxide nanowires, which may be connected using the electrodes 506 and vias 504. FIG. 5B shows a light emitting devices 514, such as a UV LEDs, and a communication module 512, which may comprise a Bluetooth Low Energy (BLE) module. As shown in FIG. 5B, two sets of 6 UV LEDs 514 may be embedded into an elastomer sheet and connected to a BLE module using shielded copper wires. FIG. 5C shows the power supply 510, the communication module 512, as well as a battery 518, and a user interface 516, which may comprise an application provided on a mobile device such as a smartphone. As shown in FIG. 5C, the two layers of FIG. 5A and FIG. 5B may be attached to each other and the BLE module and power supply may be connected to a 3.7 V battery. In some embodiments, a smartphone app or other user interface may be provided to connect to the BLE module and control switching of pairs of UV LEDs. FIG. 5D shows one example of addressing individual DEAs when pairs of UV LEDs are turned on and shining, causing a deformation at an actuated DEA 508. FIG. 5E shows another example of addressing individual DEAs when pairs of UV LEDs are turned on and shining, causing a deformation at an actuated DEA 508.

FIG. 5F shows a detail view of a light emitting device 514. FIG. 5G shows an GUI element 520 of user interface 516. In various embodiments, GUI element 520 may correspond to, and be configured to actuate, as particular actuator of an array.

The exemplary system of FIGS. 5A-5G may comprise two elastomer layers fabricated separately and attached together. In some embodiments, one layer may comprise an elastomer sheet with an array of DEAs that produce mechanical actuations, as shown in FIG. 5A, and another may comprise an elastomer sheet having embedded UV LEDs that are attached to a Bluetooth low energy (BLE) module, configured to optically addresses zinc oxide channels and control the actuation of DEAs, as shown in FIG. 5B. In some embodiments, a multilayer 6×6 array of DEAs, as in FIG. 5A, may be formed using similar methods and materials as described above, for example, performing a sequence of, first, spin coating and UV curing of an elastomer (for example, CN9028 elastomer), and second, forming arrays of 6 rectangular CNT electrodes onto the elastomer layer, oriented perpendicular to the electrode arrays on the adjacent layers. In some embodiments, concentric square-shaped rings may be printed onto each individual DEA to create larger out-of-plane deformations. In various embodiments, a 6×6 array of DEAs may be connected to high voltage and ground terminals of a miniature power supply (for example, EMCO Q50-5, XP Power) through two sets of 6 channels of percolating zinc oxide nanowires with area density of 1.0 μg mm⁻². In some embodiments, channels may be formed using similar methods and materials as described above, for example, using vacuum filtration and stamping of zinc oxide nanowires, which may be a similar method as used for forming CNT electrodes, which may simplify the integration of the high-voltage switches of zinc oxide nanowires.

Referring still to the exemplary system of FIGS. 5A-5G, interdigitated electrodes may be connected to each other using vias 504. Vias may be formed by cutting holes through elastomer layers and CNT electrodes, and filling the holes with conductive materials, such as carbon conductive grease (for example, 8481-1, MG Chemicals), as shown in FIG. 5A. As shown in FIG. 5B, light emitting devices 514, such as two sets of UV LEDs (for example, ATS2012UV365, Kingbright) may be embedded into an elastomer sheet and connected to communication module 512, which may be a BLE module (for example, CYBLE-212006-01, Cypress Semiconductor), for example, using thin shielded copper wires. LEDs may be optically coupled to the photoconductive channels. For example, the LEDs may be positioned such that when the two elastomer sheets of FIG. 5A and FIG. 5B are attached together, each LED is disposed above and faces a respective zinc oxide channel, as show in FIG. 5C.

In some embodiments, light emitting devices, such as LEDs, may be controlled using a user interface, such as a smartphone app configured to connect to the BLE module. An exemplary user interface is shown in FIG. 5C and FIG. 5G. Both the BLE module and the power supply may be powered by a 3.7 V battery with 1000 mA h capacity (for example, DTP 603450). To address an individual DEA in the 6×6 array, one pair of the LEDs may be turned on, activating a pair of zinc oxide nanowire channels, connecting the DEA to the high voltage and ground terminals of the power supply. FIG. 5D and FIG. 5E show examples of actuations of two individual DEAs.

As shown in the exemplary embodiment of FIGS. 5A-5G, addressed DEAs may deform out of plan, based on the array having a thicker passive layer on a bottom side. This thicker layer may break a symmetry along the thickness of the DEAs. The exemplary embodiment may be applied to various soft robotics, haptic device, or other embodiments. For example, when an array is placed in touch with human skin, the array may serve as a wearable haptic display, which may locally press against the skin when a respective pair of LEDs is activated.

In some embodiments, actuator response may be slower than the photoconductive responses shown in FIGS. 13A-13H, and in FIGS. 10A-10C. In some embodiments, the difference may be based on the small current that an onboard power supply and battery may provide and a small leakage current of the elastomer, which may contribute to a slower actuation and removal of actuation, respectively. In some embodiments, actuators of a DEA array may demonstrate time response similar to or matching that of the DEA shown in FIGS. 10A-10C.

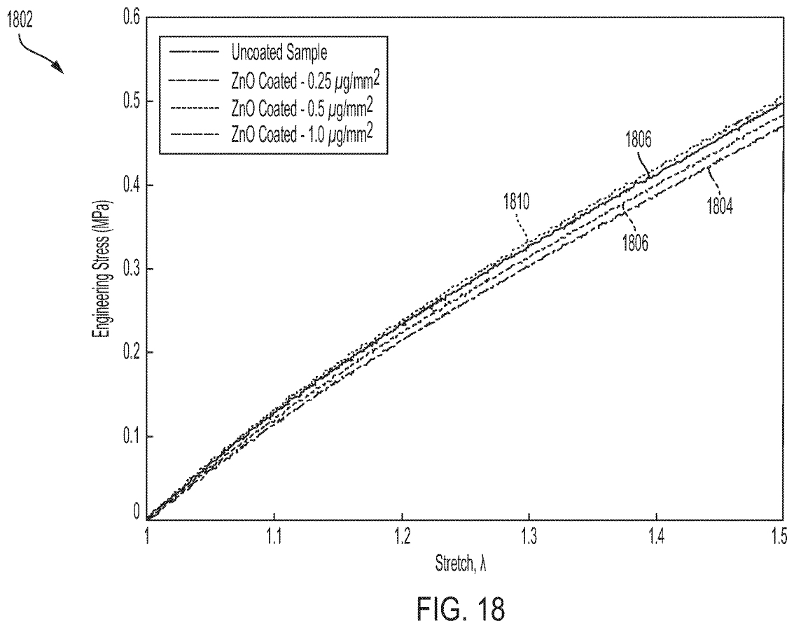

FIG. 18 shows a plot 1802 illustrating engineering stress in MPa with respect to stretch of various samples, including an uncoated sample, and zinc oxide coated samples having densities of 0.25, 0.5, and 1.0 1.0 μg mm⁻². Such samples may represent components of an actuator, for example, a compliant substrate and optical receiver of an actuator.

The characterizations of actuator responses and properties provided herein show that integrated zinc oxide nanowire networks are particularly well-suited for non-contact optical addressing of DEAs. In some embodiments, zinc oxide nanowire networks may provide an order of magnitude increase in photoconductivity in less than or fractions of a second (and/or nearly three orders of magnitude in about a second) when exposed to the UV light and may further provide a decay time of nearly one second when the UV light is removed. These responses may match a typical 1 Hz operating frequency of some DEA-based devices. Zinc oxide nanowire networks may provide an electrical breakdown strength of 6 kV per mm of channel length, which is generally suitable for withstanding DEAs' typical operating voltages of less than about 3 kV using channels with about 0.5 mm length. Zinc oxide nanowire networks may provide mechanical compliance and may be formed using simple fabrication methods follows similar processes as for compliant electrodes, allowing full integration of zinc oxide nanowire networks into DEA electrodes. This integration of the zinc oxide nanowire networks allows addressing of local actuations of DEA-based devices with high spatial resolutions and may not use any post-fabrication assembling and/or interfacing, simplifying manufacturing.

Although channels of zinc oxide nanowires activated by low numbers of UV LEDs is described herein, integration of percolating networks of zinc oxide nanowires into DEA devices, the numbers of optical receivers and light emitting devices described herein should not be understood to be limiting. Aspects of the disclosure enable a large design space for DEA-based devices.

According to various embodiments, percolating networks of zinc oxide nanowires may be used instead of CNT electrodes to serve as locally addressable electrodes themselves, which are then activated remotely by projected patterns of UV lights. Using a same material, such as zinc oxide nanowires, as both optical receivers and electrodes may provide even further simplification of manufacturing processes.

When zinc oxide nanowires are provided in conjunction with high-resolution optical displays and projectors, the percolating networks of zinc oxide nanowires can facilitate actuations with high spatial resolutions. In some embodiments, an integrated optical receiver may comprise an integrated percolating network including semiconducting nanoparticles other than zinc oxide nanowires. These other materials may be used to respond to other wavelengths or multiple light wavelengths. As merely one other exemplary embodiment, percolating networks of cadmium sulfide nanoparticles having a direct bandgap of 2.42 eV may be used and activated by visible light with wavelengths up to 550 nm.

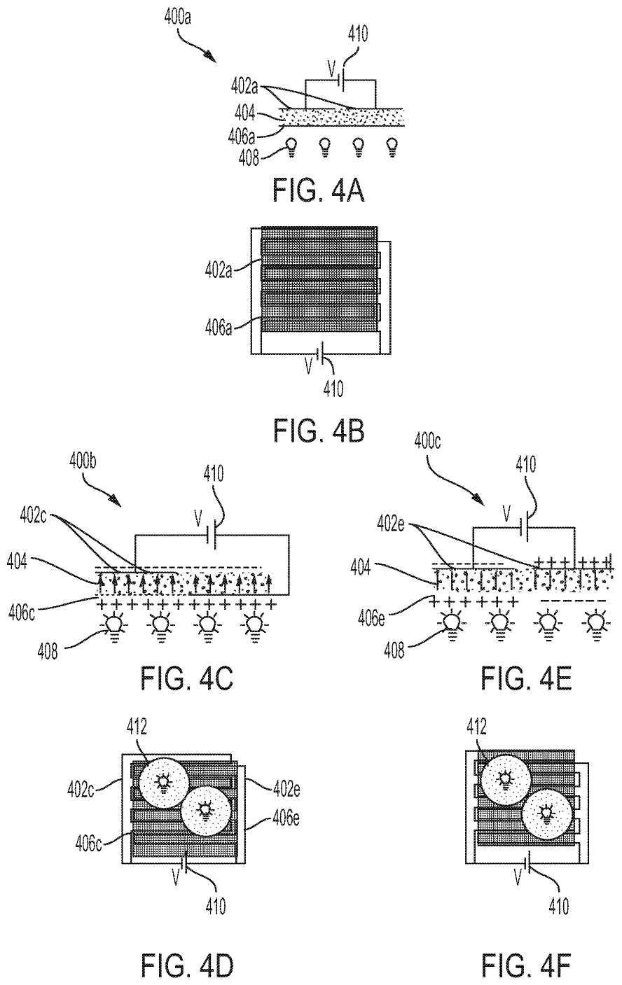

Additional exemplary operating environments are provided herein. For example, FIGS. 4A-4F show an exemplary embodiment of arrays 400a, 400b, and 400c, which may comprise arrays with floating electrodes, and which may comprise DEAs that are optically addressed to perform local actuations. FIG. 4A and FIG. 4B show an array 400a with conducting electrodes 402a, an elastomer layer 404, semiconductive floating electrodes 406a, UV LEDs 408, and power source 410. In FIG. 4A and FIG. 4B, there may be no illumination of the array, and therefore, no actuation of the array. FIG. 4C and FIG. 4D show an array 400b with conducting electrodes 402c, an elastomer layer 404, semiconductive floating electrodes 406c, UV LEDs 408, and power source 410.

According to FIGS. 4A-4F, local activation of DEAs using floating semiconducting electrodes of percolating networks of zinc oxide nanowires may be provided. When UV LEDs are turned on, the floating electrode may become conductive, allowing for redistribution of the charges, producing electric fields inside the elastomer, shown with arrows. The net charges on the floating electrode may remain zero. The plan views of FIG. 4B, FIG. 4D, and FIG. 4F shows a DEA with an elastomer layer (not shown) having comb-like positive and negative electrodes on one side, and a floating semiconducting electrode on the other side. When UV light is shone onto local areas of the DEA, only those regions 412 become conductive and allow redistribution of charges and electric field inside the elastomer, with local actuation occurring at the regions 412. Placing the arrays of FIG. 4A-4F over a light emitting device such as an optical display may therefore produce out-of-plan deformations, which in some embodiments, may be used to give an extra dimension to an optical display. Where the optical display has a high resolution, the array may employ a high resolution of the display to produce a high spatial resolution actuation.

In FIG. 4C and FIG. 4D, the UV LEDs may provide illumination causing regions 412 to have electric field, and therefore, actuation of the array at the regions 412. FIG. 4E and FIG. 4F show an array 400c with conducting electrodes 402e, an elastomer layer 404, semiconductive floating electrodes 406e, UV LEDs 408, and power source 410. In FIG. 4E and FIG. 4F, the UV LEDs may provide illumination causing regions 412 to have electric field, and therefore, actuation of the array at the regions 412.

The configuration of FIG. 4C and FIG. 4D may differ from the configuration of FIG. 4E and FIG. 4F in that the power source 410 may be coupled to the electrodes with different polarities. FIG. 4C shows a configuration where the left and right sides of the semiconducting electrodes 406c have a positive signal, and where left and right sides of the conducting electrodes 402c have a negative signal. In contrast, FIG. 4E shows a configuration where a left side of the semiconducting electrodes 406e and a right side of the conductive electrodes 402e have a positive signal, and where a right side of the semiconducting electrodes 406e and a left side of the conductive electrodes 402e have a negative signal.

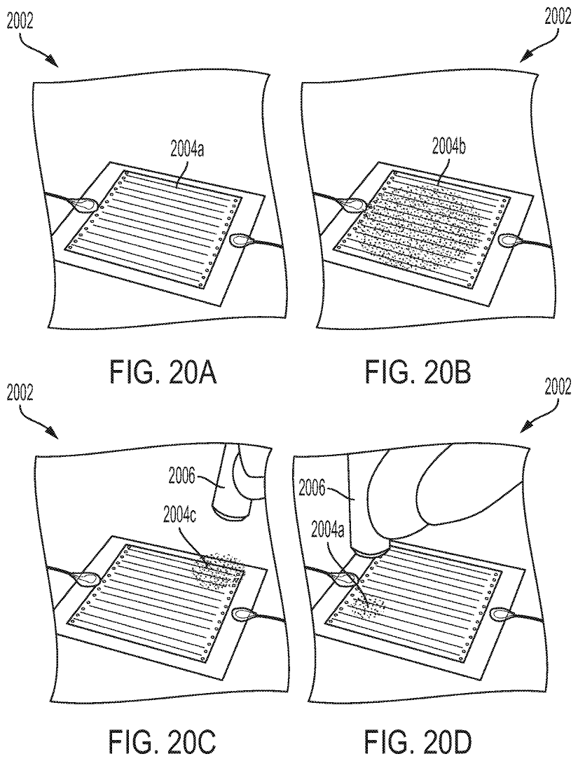

FIGS. 20A-20D show an exemplary array 2002 of actuators (which may be a flat array similar to other actuators described herein). In FIG. 20A, the array 2002 is not illuminated by light and provides a deformation pattern 2004a, which may be an undeformed state. In FIG. 20B, most of the array may be illuminated by light and the array 2002 provides a deformation pattern 2004b, where most of the array 2002 forms a bump. In FIG. 20C, one portion of the array is illuminated by light 2006, and the array provides a deformation pattern 2004c, where only a portion of the array forms a bump, at the location of the illumination. FIG. 20D shows another example where one portion of the array is illuminated by light 2006, and the array provides a deformation pattern 2004d, where only a portion of the array forms a bump, at the location of the illumination. When the light is removed, the array may return to deformation pattern 2004a of FIG. 20A. According to the exemplary embodiment of FIGS. 20A-20D, the bumps of the array 2002 may be controlled to follow illumination of the light 2006, which may be used to manipulate objects disposed above the array, for example, rolling a ball to different portions of the array, or moving other objects using the array, or may be used in other soft robotics or haptic device environments.

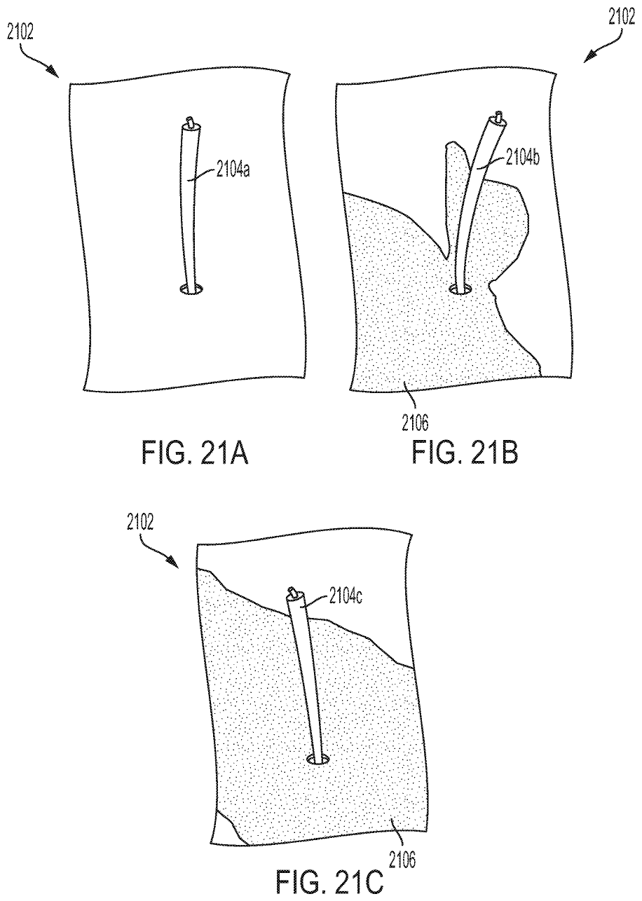

FIGS. 21A-21C show an array 2102 of actuators (which may be similar to other actuators described herein but may be arranged as a bending rod). In FIG. 21A, the array 2102 is not illuminated by light and provides a deformation pattern 2104a, which may be an undeformed state. In FIG. 21B, the bending rod array is illuminated at one side by illumination 2106, and the array provides a deformation pattern 2104b, where the bending rod array 2102 bends away from the illumination 2106, based on the location of the illumination. FIG. 21C shows another exemplary embodiment where the bending rod array is illuminated at one side by illumination 2106, and the array provides a deformation pattern 2104c, where the bending rod array 2102 bends away from the illumination 2106, based on the location of the illumination. When illumination is removed, the array may return to deformation pattern 2104a of FIG. 21A. According to the exemplary embodiment of FIGS. 21A-21C, the bending of the array 2102 may be controlled to follow illumination 2106, which may be used to manipulate objects, for example, as a pseudo-finger or other manipulation device, or may be used in other soft robotics or haptic device environments.

Integration of percolating networks of zinc oxide nanowires into DEAs, operating at high voltages, provides optical addressing of individual actuators in a noncontact manner using common low-voltage electronics. As described herein, channels of zinc oxide nanowires may withstand high operating voltages of DEAs in the absence of UV light and may exhibit fast response and large photocurrent to dark current ratio under high bias voltages. Exemplary embodiments of optical addressing of a 6×6 array of DEAs with integrated channels of zinc oxide nanowires is also provided.

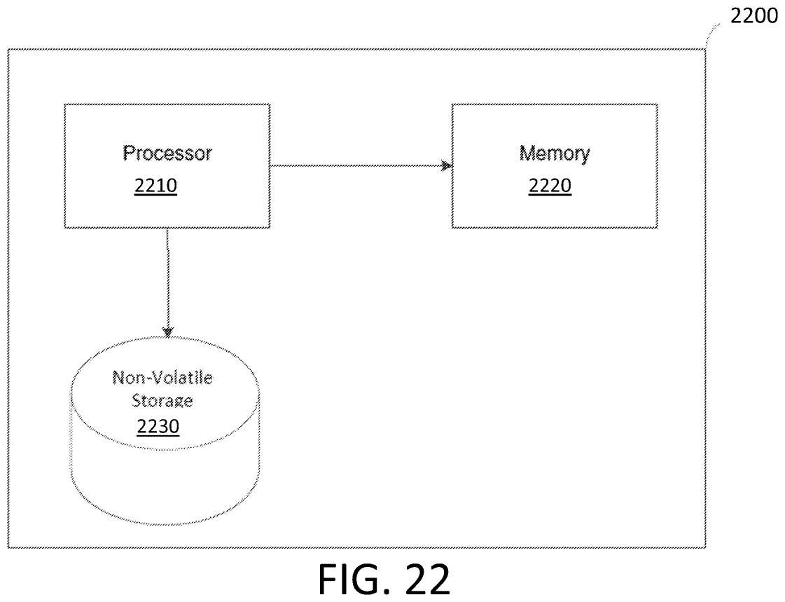

An illustrative implementation of a computer system 2200 that may be used in connection with any of the embodiments of the disclosure provided herein is shown in FIG. 22. The computer system 2200 may include one or more processors 2210 and one or more articles of manufacture that comprise non-transitory computer-readable storage media (e.g., memory 2220 and one or more non-volatile storage media 2230). The processor 2210 may control writing data to and reading data from the memory 2220 and the non-volatile storage device 2230 in any suitable manner. To perform any of the functionality described herein, the processor 2210 may execute one or more processor-executable instructions stored in one or more non-transitory computer-readable storage media (e.g., the memory 2220), which may serve as non-transitory computer-readable storage media storing processor-executable instructions for execution by the processor 2210.

The terms “program” or “software” are used herein in a generic sense to refer to any type of computer code or set of processor-executable instructions that can be employed to program a computer or other processor to implement various aspects of embodiments as discussed above. Additionally, it should be appreciated that according to one aspect, one or more computer programs that when executed perform methods of the disclosure provided herein need not reside on a single computer or processor but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in one or more non-transitory computer-readable storage media in any suitable form. For simplicity of illustration, data structures may be shown to have fields that are related through location in the data structure. Such relationships may likewise be achieved by assigning storage for the fields with locations in a non-transitory computer-readable medium that convey relationship between the fields. However, any suitable mechanism may be used to establish relationships among information in fields of a data structure, including through the use of pointers, tags or other mechanisms that establish relationships among data elements.

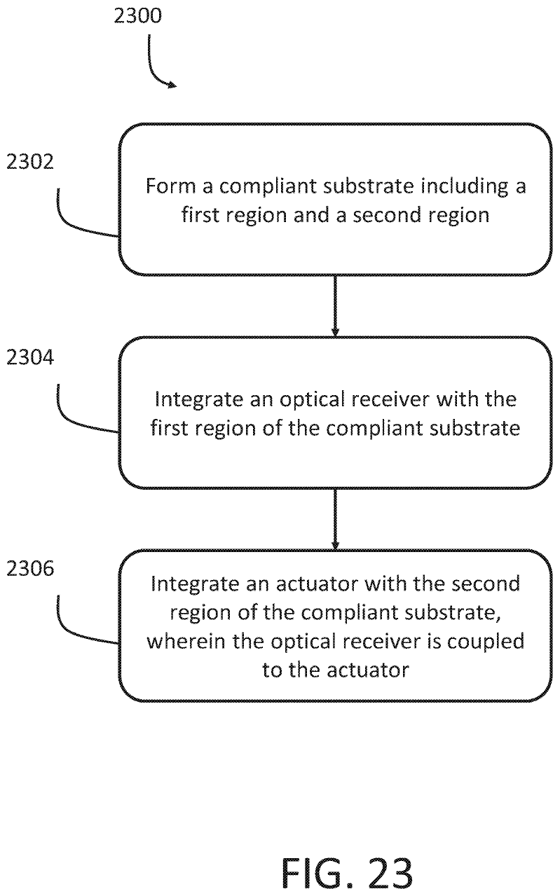

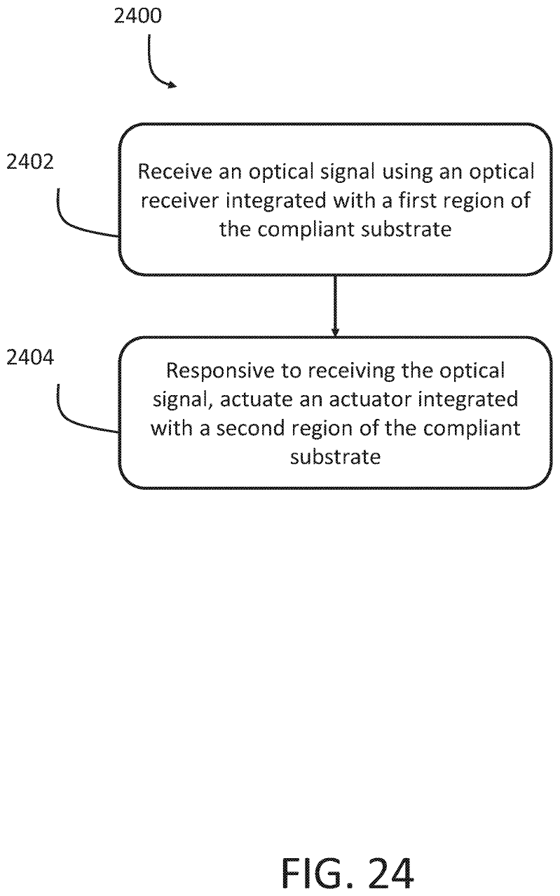

Also, various inventive concepts may be embodied as one or more processes, of which examples (for example, FIGS. 23 and 24) are provided. The acts performed as part of each process may be ordered in any suitable way. Accordingly, embodiments may be constructed in which acts are performed in an order different than illustrated, which may include performing some acts simultaneously, even though shown as sequential acts in illustrative embodiments.

FIG. 23 shows an exemplary process flow 2300 of a method of manufacturing an actuator, which may be an addressable actuator. Process flow 2300 includes act 2302, act 2304, and act 2306. At act 2302, the process flow 2300 may include forming a compliant substrate including a first region and a second region. At act 2304, the process flow 2300 may include integrating an optical receiver with the first region of the compliant substrate. At act 2306, the process flow 2300 may include integrating an actuator with the second region of the compliant substrate, wherein the optical receiver is coupled to the actuator.

FIG. 24 shows an exemplary process flow 2400 of a method of operating an actuator, which may be an addressable actuator comprising a compliant substrate. Process flow 2400 includes act 2402 and act 2404. At act 2402, the process flow 2400 may include receiving an optical signal using an optical receiver integrated with a first region of the compliant substrate. At act 2404, the process flow 2400 may include responsive to receiving the optical signal, actuating an actuator integrated with a second region of the compliant substrate.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately,” “about,” and “substantially” may be used to mean within ±20% of a target value in some embodiments, within ±10% of a target value in some embodiments, within ±5% of a target value in some embodiments, within ±2% of a target value in some embodiments. The terms “approximately,” “about,” and “substantially” may include the target value.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

What is claimed is:

1. An addressable actuator, comprising:
a compliant substrate including a first region and a second region;
an optical receiver integrated with the first region of the compliant substrate; and
an actuator integrated with the second region of the compliant substrate,
wherein the optical receiver is coupled to the actuator.

2. An addressable actuator array, comprising:
a plurality addressable actuators,
wherein each addressable actuator of the plurality of addressable actuators comprises the addressable actuator of claim 1.

3. The addressable actuator array of claim 2, wherein:
each addressable actuator of the plurality of addressable actuators is independently optically addressable.

4. A system comprising:
the addressable actuator of claim 1; and
a light emitting device,
wherein the light emitting device is optically coupled to the optical receiver.

5. The addressable actuator of claim 1, wherein the optical receiver comprises a photoconductive channel integrated with the actuator.

6. The addressable actuator of claim 5, wherein the photoconductive channel is compliant.

7. The addressable actuator of claim 1, wherein the compliant substrate comprises an elastomer.

8. The addressable actuator of claim 1, wherein the optical receiver is electrically coupled to the actuator.

9. The addressable actuator of claim 8, wherein the optical receiver is directly electrically coupled to the actuator.

10. The addressable actuator of claim 1, wherein the optical receiver comprises a semiconductor film.

11. The addressable actuator of claim 1, wherein the optical receiver comprises a plurality of zinc oxide nanowires disposed in the first region of the compliant substrate.

12. The addressable actuator of claim 11, wherein the plurality of zine oxide nanowires comprise a percolating network.

13. The addressable actuator of claim 1, wherein the actuator comprises a capacitor, the capacitor comprising:
a first electrode;
a second electrode; and
a portion of the compliant substrate disposed between the first electrode and the second electrode.

14. The addressable actuator of claim 13, wherein the capacitor is configured to:
receive a signal from the optical receiver; and
responsive to receiving the signal, compress a thickness of the portion of the compliant substrate disposed between the first electrode and the second electrode.

15. The addressable actuator of claim 14, wherein the capacitor is further configured to:
responsive to receiving the signal, laterally expand the portion of the compliant substrate disposed between the first electrode.

16. The addressable actuator of claim 13, wherein:
the optical receiver is formed of a first material; and
at least one of the first electrode or the second electrode is formed of the first material.

17. The addressable actuator of claim 16, wherein the first material comprises zinc oxide.

18. The addressable actuator of claim 17, wherein the optical receiver, the first electrode, and the second electrode are formed of zinc oxide nanowires.

19. The addressable actuator of claim 1, wherein the first region and the second region overlap.

20. A method of manufacturing an addressable actuator, comprising:
forming a compliant substrate including a first region and a second region;
integrating an optical receiver with the first region of the compliant substrate; and
integrating an actuator with the second region of the compliant substrate,
wherein the optical receiver is coupled to the actuator.

21. A method of manufacturing an addressable actuator array, comprising:
forming a plurality of addressable actuators, comprising:
forming each addressable actuator of the plurality of addressable actuators according to the method of claim 20.

22. The method of claim 21, wherein:
each addressable actuator of the plurality of addressable actuators is independently optically addressable.

23. A method of manufacturing a system, comprising:
forming an addressable actuator according to the method of claim 21;
providing a light emitting device; and
optically coupling the light emitting device to the optical receiver.

24. The method of claim 21, wherein integrating an optical receiver comprises integrating a photoconductive channel with the actuator.

25. The method of claim 24, wherein the photoconductive channel is compliant.

26. The method of claim 21, wherein forming the compliant substrate comprises forming the compliant substrate with an elastomer.

27. The method of claim 21, further comprising electrically coupling the optical receiver to the actuator.

28. The method of claim 27, wherein electrically coupling the optical receiver to the actuator comprises directly electrically coupling the optical receiver to the actuator.

29. The method of claim 21, wherein integrating the optical receiver comprises forming the optical receiver with a semiconductor film.

30. The method of claim 21, wherein integrating the optical receiver comprises forming the optical receiver with a plurality of zinc oxide nanowires in the first region of the compliant substrate.

31. The method of claim 30, wherein forming the optical receiver with the plurality of zinc oxide nanowires comprises forming a percolating network with the plurality of zine oxide nanowires.

32. The method of claim 21, wherein integrating the actuator comprises forming a capacitor, comprising:
forming a first electrode; and
forming a second electrode,
wherein a portion of the compliant substrate is disposed between the first electrode and the second electrode.

33. The method of claim 32, wherein the capacitor is configured to:
receive a signal from the optical receiver; and
responsive to receiving the signal, compress a thickness of the portion of the compliant substrate disposed between the first electrode and the second electrode.

34. The method of claim 33, wherein the capacitor is further configured to:
responsive to receiving the signal, laterally expand the portion of the compliant substrate disposed between the first electrode and the second electrode.

35. The method of claim 32, comprising:
forming the optical receiver of a first material; and
forming at least one of the first electrode or the second electrode of the first material.

36. The method of claim 35, comprising:
forming the optical receiver of zinc oxide; and
forming at least one of the first electrode or the second electrode of zinc oxide.

37. The method of claim 36, comprising forming the optical receiver, the first electrode, and the second electrode of zinc oxide nanowires.

38. The method of claim 21, wherein integrating the optical receiver with the first region of the compliant substrate and integrating the actuator with the second region of the compliant substrate comprise:
integrating the optical receiver with the first region of the compliant substrate and integrating the actuator with the second region of the compliant substrate with the first region and the second region overlapping.

39. A method of operating an addressable actuator comprising a compliant substrate, the method comprising:
receiving an optical signal using an optical receiver integrated with a first region of the compliant substrate; and
responsive to receiving the optical signal, actuating an actuator integrated with a second region of the compliant substrate.

40. A method of operating an addressable actuator array, comprising:
operating a plurality of addressable actuators, comprising:
operating each addressable actuator of the plurality of addressable actuators according to the method of claim 39.

41. The method of claim 40, wherein:
each addressable actuator of the plurality of addressable actuators is independently optically addressable.

42. A method of operating a system comprising:
operating the addressable actuator according to the method of claim 39; and
sending the optical signal using a light emitting device,
wherein the light emitting device is optically coupled to the optical receiver.

43. The method of claim 39, wherein the optical receiver comprises a photoconductive channel integrated with the actuator.

44. The method of claim 43, wherein the photoconductive channel is compliant.

45. The method of claim 39, wherein the compliant substrate comprises an elastomer.

46. The method of claim 39, wherein the optical receiver is electrically coupled to the actuator.

47. The method of claim 46, wherein the optical receiver is directly electrically coupled to the actuator.

48. The method of claim 39, wherein the optical receiver comprises a semiconductor film.

49. The method of claim 39, wherein the optical receiver comprises a plurality of zinc oxide nanowires disposed in the first region of the compliant substrate.

50. The method of claim 49, wherein the plurality of zine oxide nanowires comprise a percolating network.

51. The method of claim 39, wherein the actuator comprises a capacitor, the capacitor comprising:
a first electrode;
a second electrode; and
a portion of the compliant substrate disposed between the first electrode and the second electrode.

52. The method of claim 51, wherein actuating the actuator comprises actuating the capacitor, comprising:
receiving a signal from the optical receiver; and
responsive to receiving the signal, compressing a thickness of the portion of the compliant substrate disposed between the first electrode and the second electrode.

53. The addressable actuator of claim 52, wherein actuating the capacitor further comprises:
responsive to receiving the signal, laterally expanding the portion of the compliant substrate disposed between the first electrode and the second electrode.

54. The method of claim 51, wherein:
the optical receiver is formed of a first material; and
at least one of the first electrode or the second electrode is formed of the first material.

55. The method of claim 54, wherein the first material comprises zinc oxide.

56. The method of claim 55, wherein the optical receiver, the first electrode, and the second electrode are formed of zinc oxide nanowires.

57. The method of claim 39, wherein the first region and the second region overlap.
